(19) United States
(12) Patent Application Publication
(10) Pub. No.: US 2022/0352685 A1
(43) Pub. Date: Nov. 3, 2022

(54) HIGHLY-INTEGRATED COMPACT DIFFRACTION-GRATING BASED SEMICONDUCTOR LASER

(71) Applicant: OptoNet Inc., Evanston, IL (US)

(72) Inventor: Yingyan Huang, Wilmette, IL (US)

(73) Assignee: OptoNet Inc., Evanston, IL (US)

(21) Appl. No.: 17/733,104

(22) Filed: Apr. 29, 2022

Related U.S. Application Data
(60) Provisional application No. 63/182,768, filed on May 1, 2021.

(51) Int. Cl. H01S 3/063; H01S 5/0234; H01S 5/343; H01S 3/08; H01S 3/04; B29D 11/00

(52) U.S. Cl. CPC H01S 3/063; H01S 5/0234; H01S 5/3434; H01S 3/08059; H01S 3/08009; H01S 3/0407; B29D 11/0074

(57) ABSTRACT

It is an aim of the present invention to provide ultra-compact highly-integrated diffraction-grating semiconductor lasers on chips. Various embodiments combined enable the lasers to be compact in size, light weight, mechanically rugged, low in manufacturing cost, and in some cases high in electrical wall-plugged power efficiency or high in optical power output, comparing to typical lasers based on discrete optical components.

### CROSS-REFERENCES TO RELATED APPLICATIONS

The present invention claims priority to U.S. Provisional Application No. 63/182,768, filed May 1, 2022, titled “Ultra-Compact Multi-Wavelength-Channel-Capable Integrated Semiconductor Laser”, the content of which is incorporated by reference in its entirety.

The present invention incorporates by reference U.S. Provisional Applications Nos. 62/399,483, filed Sep. 25, 2016, titled “Highly Integrated Compact Diffraction Grating Based Semiconductor Laser;” in its entirety. The present invention also references the following patents: (1) (referred to as PGR1) U.S. Pat. No. 7,283,233, Issue Date: 16 Oct. 2007, titled “Curved grating spectrometer with very high wavelength resolution;” (2) (referred to as PGR2) U.S. Pat. No. 7,623,235, Issue Date: 24 Nov. 2009, “Curved grating spectrometer with very high wavelength resolution;” (3) (referred to as PGR3) U.S. Pat. No. 8,462,338, Issue Date: 11 Jun. 2013, “Curved grating spectrometer and wavelength Multiplexer or Demultiplexer with very high wavelength resolution;” (4) (referred to as PGR4) U.S. Pat. No. 9,612,155 B2, Issue Date: 4 Apr. 2017, “CURVED GRATING SPECTROMETER AND WAVELENGTH MULTIPLEXER OR DEMULTIPLEXER WITH VERY HIGH WAVELENGTH RESOLUTION;” (5) (referred to as PGR5) U.S. Pat. No. 8,854,620 B2, Issue Date: 7 Oct. 2014, “CURVED GRATING SPECTROMETER AND WAVELENGTH MULTIPLEXER OR DEMULTIPLEXER WITH VERY HIGH WAVELENGTH RESOLUTION;” (6) (referred to as PGR6) Application number PCT/US2015/049386, application Date: 10 Sep. 2015, “CURVED GRATING SPECTROMETER AND WAVELENGTH MULTIPLEXER OR DEMULTIPLEXER WITH VERY HIGH WAVELENGTH RESOLUTION;” (7) (referred to as PGR7) U.S. application Ser. No. 15/362,037 (US Application: US20170102270A1), application Date: 28 Nov. 2016, “CURVED GRATING SPECTROMETER AND WAVELENGTH MULTIPLEXER OR DEMULTIPLEXER WITH VERY HIGH WAVELENGTH RESOLUTION.”

### BACKGROUND

The present invention relates to semiconductor photonic, discrete optic, integrated optic, and opto-electronic devices. In particular, the present invention relates to highly-integrated compact semiconductor laser on a single chip based on integrated diffraction grating.

Present semiconductor laser system based on diffraction grating typically make use of bulk optical diffraction grating and the use of discrete optical components such as lenses that are tedious to be aligned with each other optically. Such semiconductor laser systems based on diffraction grating are sometime referred to as diffraction-grating semiconductor lasers. They have the advantage of wavelength selectivity utilizing diffraction grating or utilizing grating to combined a few wavelengths together into a single output mirror. However, laser systems based on discrete optical components are mechanically fragile. They are typically very heavy and cannot be easily carried or moved around.

There is an unmet need in the art for an integrated laser system on a single integrated chip that is very compact in size, very light weight, mechanically very rugged, low in manufacturing costs, and high in wall-plugged electrical power efficiency.

### SUMMARY

It is an aim of the present invention to provide ultra-compact highly-integrated diffraction-grating semiconductor lasers on chips that are compact in size, light weight, mechanically rugged, low in manufacturing cost, and in some cases high in electrical wall-plugged power efficiency or high in optical power output, comparing to typical lasers based on discrete optical components.

Another objective of this invention is to provide an integrated semiconductor laser system on a single semiconductor chip based on the integration of a few key integrated optical components that result in an efficient laser on a single chip with multiple functional configurations.

The present invention has overcome the aforementioned limitations of the prior arts on diffraction-grating based semiconductor laser systems utilizing discrete optical components.

In one embodiment of the present invention, a laser system is integrated on a single integrated chip via the use of an integrated curved diffraction grating combined with one or more integrated Bragg-grating reflectors, that enables a fully integrated diffraction-grating based laser that do not need the use of any optical lens.

In another embodiment of the present invention, one or more photonic devices are integrated on a substrate. The photonic devices comprise one or more optical gain material areas. One or more passive photonic components are fabricated on a passive waveguiding layer. The passive photonic components contain at least a curved optical grating and at least one wavelength-channel-combined-arm Bragg reflector. The method further transfers a thin layer of material capable of providing optical power amplification.

In another embodiment of the present invention, the wavelength-channel-combined-arm Bragg reflector is fabricated into a planar waveguiding layer.

In as yet another embodiment of the present invention, the wavelength-channel-combined-arm Bragg reflector is fabricated into a planar waveguiding layer with high-refractive index contrast, resulting in a broad optical bandwidth of reflection and transmission.

In as yet another embodiment of the present invention, the planar waveguiding layer is silicon.

In as yet another embodiment of the present invention, the number of reflecting teeth in the wavelength-channel-combined-arm Bragg reflector is adjusted to provide a highly reflecting beam-power reflector or a partially-transmitting beam-power reflector.

In as yet another embodiment of the present invention, the optical beam is confined in the direction perpendicular to the substrate surface via planar or channel waveguides, and a curved diffraction grating is fabricated into a planar waveguiding area with the surfaces of the grating teeth approximately perpendicular to the substrate plane.

In as yet another embodiment of the present invention, one side of the optical beam propagating path intersects with the wavelength-channel-combined-arm Bragg reflector, and another side of the optical beam propagating path intersects with the curved diffraction grating is positioned the mouth of a channel waveguide (called wavelength-channel-separated waveguide mouth).

In as yet another embodiment of the present invention, the optical power in a wavelength of light in the optical beam propagating toward the wavelength-channel-combined-arm Bragg-grating reflector is reflected back either fully or partially by the wavelength-channel-combined-arm Brag-grating reflector toward the curved diffraction grating and is further diffracted by the curved diffraction grating to enter the said wavelength-channel-separated waveguide mouth.

In as yet another embodiment of the present invention, there are two or more of the said waveguide mouths, with each mouth receiving a wavelength of the light beam reflecting back from the wavelength-channel-combined-arm Bragg reflector towards the grating.

In as yet another embodiment of the present invention, the beam entering the mouth of a channel waveguide is guided via a linear or a curvilinear path along a channel waveguide to an optical gain region.

In as yet another embodiment of the present invention, the optical gain region is composed of an active gain material layer forming a gain channel waveguide bonded on top of a passive transparent channel waveguide.

In as yet another embodiment of the present invention, the optical beam energy in the passive transparent channel waveguide is transferred from the passive channel waveguide to the gain material layer via laterally tapering structures on at least one of the passive channel waveguiding layer or the gain channel waveguide layer.

In as yet another embodiment of the present invention, the optical beam energy in the gain channel waveguide is transferred from the gain channel waveguide to the passive channel waveguide via laterally tapering structures on at least one of the passive channel waveguiding layer or the gain channel waveguide layer.

In as yet another embodiment of the present invention, the optical beam energy propagating through the gain region from the grating-facing waveguide mouth is entered into a passive channel waveguide. The beam in the passive channel waveguide is then reflected back either fully or partially via a Bragg-grating reflector.

In yet another embodiment of the present invention, the curved diffraction grating is designed such that the beam size in direction parallel to the plane of the substrate is larger at the wavelength-channel-combined-arm Bragg-grating reflector than at the wavelength-channel-separated waveguide mouth.

In yet another embodiment of the present invention, the curved grating is designed such that the beam size in direction parallel to the plane of the substrate (called the horizontal mode size) is small at the wavelength-channel-separated waveguide mouth, but is large at the wavelength-channel-combined-arm Bragg-grating reflector. There may be one or more than one waveguide mouths with each mouth receiving a wavelength channel. This enables the intensity at the wavelength-channel-combined-arm Bragg-grating reflector that would have higher optical power (by combining the many wavelength channels) to be made low or comparable to the intensity of the light beam at each of the wavelength-channel-separated waveguide mouth that would receive light energy in only one of the wavelength channels. The lowered intensity in the relatively higher-power beam at the wavelength-channel-combined-arm Bragg-grating reflector reduces the chance of optical damage at the wavelength-channel-combined-arm Bragg reflector region.

In as yet another embodiment of the present invention, the wavelength-channel-combined-arm Bragg-grating reflector is made of Bragg grating's teeth that are curved in shape (instead of linear in shape like a straight line), so as to achieve larger horizontal beam size and hence lower beam intensity at the wavelength-channel-combined-arm Bragg-grating reflector.

In as yet another embodiment of the present invention, the optical beam energy propagating towards the wavelength-channel-combined-arm Bragg-grating reflector is partially transmitted at the reflector to an optical-fiber coupler such as a surface-grating based optical fiber coupler, or a planar (horizontal) beam-transformer based optical fiber coupler.

In as yet another embodiment of the present invention, the spatial region that brings in the optical fiber to the optical-fiber coupler is hermetically sealed.

In as yet another embodiment of the present invention, the surface-grating based optical fiber coupler is composed of a surface grating that emits the beam in a direction approximately perpendicular to a substrate plane and a Fresnel lens structure that further reduces a beam diameter emitted to a smaller value.

In as yet another aspect of the present invention, each of the photonic devices is sandwiched from at least one of the top or the bottom via cooling fixtures that allow water cooling of the photonic device.

### BRIEF DESCRIPTION OF THE DRAWINGS

The preferred embodiments of the invention will hereinafter be described in conjunction with the appended drawings provided to illustrate but not to limit the invention, wherein like designations denote like elements, and in which:

FIG. 1 is a diagram illustrating: (a) Cross-section view of a silicon waveguide on a silicon-on-insulator (SOI) substrate; (b) Schematic view of a strongly-guiding silicon channel waveguide; (c) Passive devices are first fabricated on the silicon layer; (d) A InP substrate grown with an epitaxial layer with quantum well is turned up-side down and bonded to the silicon surface; (e) The InP substrate is removed via selective chemical etching, leaving the bonded few-micron thick III-V semiconductor epitaxial layer with quantum well on the silicon surface; (f) Cross-section view of a “gain waveguide” realized by bonding III-V epitaxial layer such as InP based material system with PN junction and quantum wells on a silicon waveguide on SOI; (g) An exemplary structure for the epitaxial layer and wafer that is to be used for the thin-film transfer of an active layer.

FIG. 2 is a diagram illustrating as a top view the planar geometry of an exemplar laser chip with straight waveguide connection (SWGC) geometry for the gain element waveguide mouth arrays connecting to the gain section array.

FIG. 3 is a diagram illustrating the geometry of a diffraction grating based laser chip with curvilinear waveguide connection (CWGC) geometry for the gain element waveguide mouth arrays connecting to the gain section array.

FIG. 4 is a diagram illustrating: (a) Echelle-Rowland grating design rule requires the exit slits (or waveguides) be placed on a Rowland circle of raduis R. (b) The generation of grating teeth for Echelle-Rowland grating is done by constant spacing along a chord and placing the teeth on a circle with radius equal to 2*R.

FIG. 5 is a diagram illustrating: (a) a diffraction grating design in which the output slits are placed along a locus that is nearly a straight line, instead of on a circle; (b) the rays of the beams at the exit slits showing that they are basically aberration-free over a wide 300 nm wavelength range; (c) the output spectrum of the grating showing high spectral power rejection for adjacent channels.

FIG. 6 is a diagram illustrating: (a) that a diffraction grating can be designed so the entrance beam would be a near-collimated beam that would have a wide beam size; (b) a ray diagram generated for the diffraction grating shown in (a); (c) the constraints in ER-grating; (d) An SEM photo of an exemplary chip fabricated with the diffraction grating with 100 GHz dense wavelength division multiplexing (DWDM) channel spacing.

FIG. 7 is a diagram illustrating: (a) a schematic for the RMS (regular mode size) structure; (b) A schematic for the LMS (large mode size) structure.

FIG. 8 is a diagram illustrating: (a) a simulated mode size in the RMS structure for the first-order fundamental guided mode; (b) a simulated mode size in the LMS structure for the first-order fundamental guided mode.

FIG. 9 is a diagram illustrating: (a) a vertical beam coupling structure in 3D for the RMS (regular mode size) structure case; (b) a side view showing schematically the mode transformation in the vertical beam coupling structure of (a); (c) a side view showing schematically the mode transformation in the vertical beam coupling structure of a LMS (large mode size) structure case.

FIG. 10 is a diagram illustrating the simulation of vertical beam coupling showing the mode evolutions moving the beam from the silicon layer to the gain waveguide layer in the RMS (regular mode size) structure at different sections (A-F) involving a few sets of tapering teeth.

FIG. 11 is a diagram illustrating: (a) High reflector design. Top picture shows the top view and bottom picture shows the side view of the etched down Si layer forming a Bragg grating with 10 teeth; (b) Reflection spectrum from simulation showing high reflectivity (˜99%) over a broad >200 nm bandwidth.

FIG. 12 is a diagram illustrating: (a) Output mirror design showing a Bragg grating with 3 teeth. The grating lines are curved to match the curved phase front of the converging optical beam; (b) Reflection spectrum from simulation showing reflectivity ˜50% over a broad >200 nm bandwidth.

FIG. 13 is a diagram illustrating: (a) a structure of the horizontal mode filter; (b) a simulated fundamental (or first-order) mode; (c) a simulated second-order mode, showing a wider mode width than the horizontal first order mode. The loss coefficient obtained from the simulation with the structure in (a) shows significant absorption for the horizontal higher-order modes.

FIG. 14 is a diagram illustrating: (a) a structure of the vertical mode filter; (b) a simulated fundamental (or first-order) mode; (c) a simulated second-order vertical mode, showing a wider mode width than the first order mode. The loss obtained from the simulation with the structure in (a) shows significant absorption for the vertical higher-order modes.

FIG. 15 is a diagram illustrating: (a) a schematic showing the structure of a fiber coupler with changing duty cycle for the teeth to give a near Gaussian intensity profile to match the optical fiber mode shape; (b) a schematic showing a scheme with a pair of shallow and deep etched teeth to increase the power emission upward and reduce the emission downward; (c) a schematic showing the use of an integrated Fresnel lens to focus a wide beam into a single-mode fiber with a fiber core diameter smaller than the beam mode width on silicon; (d) a cross section showing the removal of the silicon substrate and metal coating that would help to reflect the light back to the fiber. It also shows a tube holding the fiber that would be soldered down in inert gas environment to provide a dust and moisture free hermetic sealing of the fiber coupling area. The hermetic sealing would prevent the fiber end facet from power damage due to surface contamination over time. The cooling water below the coupling area would help to cool the area.

FIG. 16 is a diagram illustrating a cooling system design with: (a) a side view; (b) a top view.

FIG. 17 is a diagram illustrating a schematic showing a scheme that involves P and N electrical contacts from only the top side with: (a) a side view; (b) a top view showing how the relatively narrow P and N electrodes along the waveguiding direction of the gain elements are connected in perpendicular direction by a series of wide electrodes.

FIG. 18 is a diagram illustrating a schematic showing a scheme that involves silicon substrate removal and electrical contact from both the top and bottom side with: (a) an overall view; (b) a more detail view of the chip contacts and current flow.

Skilled artisans will appreciate that the elements in the figures are illustrated for simplicity and clarity, and have not necessarily been drawn to scale. For example, the dimensions of some of the elements in the figures may be exaggerated, relative to the other elements, to help in improving understanding of the embodiments of the present invention. Also, specific materials or dimensions shown in the figures are for illustration purposes and are not meant to limit the scopes of the present invention.

### DETAILED DESCRIPTION

In the present description, certain terms have been used for brevity, clearness and understanding. No unnecessary limitations are to be applied therefrom beyond the requirement of the prior art because such terms are used for descriptive purposes only and are intended to be broadly construed. The different systems and methods described herein may be used alone or in combination with other systems and methods. Various equivalents, alternatives and modifications are possible within the scope of the appended claims. Each limitation in the appended claims is intended to invoke interpretation under 35 U.S.C. § 112, sixth paragraph, only if the terms “means for” or “step for” are explicitly recited in the respective limitation.

### Motivations of the Present Invention

Lasers or laser systems based on discrete optical components are mechanically fragile. They are typically very heavy and cannot be easily carried or moved around. The main focus of this invention is a highly integrated laser system on a single integrated chip that is very compact in size, very light weight, mechanically very rugged, low in manufacturing costs, and high in wall-plugged electrical power efficiency, comparing to high-power lasers based on discrete optical components generally.

This invention focuses on highly-integrated compact semiconductor laser on a single chip based on integrated diffraction grating. Each laser is made as a single integrated chip using a full-wafer-level process without the need to align discrete optical components. The laser is capable of lasing at either a single wavelength or a plurality of optical wavelengths with use of a single curved diffraction grating, the use of one or more broadband integrated Bragg-grating reflectors, and other integrated optical components. The entire integrated laser can be configured to achieve various functional operations. The various functional operations include the case with a single output waveguide that combines two or more lasing wavelengths together (referred to as combined multi-wavelength single-output (CMWSO) laser), thereby achieving a higher output power. There are other functional operations that can be achieved with use of the various integrated components.

A focus of this invention is a laser system on a single integrated chip, based on the use of an integrated curved diffraction grating combined with one or more integrated Bragg-grating reflectors, that enables a fully integrated diffraction-grating based laser that do not need the use of any optical lens. Furthermore, the integrated laser system can be configured to achieved various different functional operations. The integrated laser system of the present invention is compact in size, light in weight, mechanically rugged, lower in manufacturing cost, and high in electrical wall-plugged power efficiency, comparing to lasers based on discrete optical components.

Each semiconductor integrated laser system of the present invention is made as a single integrated semiconductor chip using a full-wafer-level process without the need to align discrete optical components. This lowers the cost of production, reduces the size and weight of the lasers substantially, and makes the lasers much more rugged. In the case of the higher-power CMWSO lasers, the lasers will have superb beam focusing capability (with beam quality factor M²˜1) and high brightness B. The laser wavelength can be at near infrared (e.g., 1550 nm) or at any other wavelengths by scaling the design accordingly. The production costs of these integrated laser systems can be much lower than the production cost of laser systems based on discrete components, and the output powers of these integrated lasers can be delivered into single-mode optical fibers.

### Broad Overview of the Present Invention

The present invention is about a method to design and realize a class of lasers on a photonic integrated circuit that is efficient and capable of integration with other photonic devices. The geometry for the lasers is based on the use of “integrated diffraction grating” as part of the laser design. The diffraction grating enables multiple lasing wavelength channels to be combined into a single output on the chip. As a result, this class of lasers is capable of a wide variety of functionalities, including high output power by combining the output powers of many lasing wavelengths into a single output waveguide. The output can be further coupled to a single optical fiber. Thus, this class of lasers would have applications ranging from efficient single-wavelength lasers made on an integrated photonic chip, lasers capable of combining with electronic integrated circuits on a single chip, multi-wavelength lasers for optical communications that need many wavelength channels to transmit optical data, to high-power lasers that can reach watts level optical power output in a single-mode optical fiber and many others.

One characteristic of the laser structure in the present invention is its use of an optical thin-film transfer (OTFT) structure combined with an integrated diffraction grating as part of the laser geometry. For the purposes of this application, the term a “thin film” will be taken to mean a film with a thickness less than 10 times the optical wavelength used in the device. The optical thin-film transfer structure enables efficient devices by providing an efficient way to combine low-optical-loss passive optical waveguides with material layers that can provide optical gain. The diffraction grating geometry enables multiple-wavelength lasing or single-wavelength lasing with high spectral purity (i.e., a narrow spectral linewidth for the lasing mode). The OTFT structure-based platform forms the three-dimensional device structure for the lasers of the present invention. The diffraction grating based geometry then enables the unique advantages and functionalities of the lasers. The class of lasers of the present invention will be referred to as Integrated Diffraction-Grating-based Optical Thin-Film-Transferred lasers, or as IDG-OTFT lasers.

To describe the IDG-OTFT lasers in detail, below the application first describes the OTFT structure based photonic integrated circuit platform, referred to as OTFT platform or as OTFTP, then describes the geometry of the laser design involving integrated diffraction grating.

Optical-Thin-Film-Transfer Based Photonic Integrated Circuit Platform

The basic three-dimensional structure of the IDG-OTFT lasers is based on an Optical Thin-Film-Transfer Structure called the OTFT platform. The OTFT platform is attractive as it enables high quality integration of passive and active optical materials on a single chip. Passive optical materials are important to make low-optical-loss optical waveguides and optical diffraction grating needed for the lasers. Active optical materials are needed for example to provide the optical gain needed (e.g., via current injection into a quantum-well structure) for achieving lasing. Before describing the geometry of the laser device, first the three-dimensional structure of the OTFT platform that it is based on is described.

As is known to those skilled in the art, there are various optically transparent materials that can be used as the passive layer material. For the purpose of illustration and not limitation, this application will describe the OTFT platform by using silicon as the exemplary passive material and will focus on 1550 nm wavelength range for which the silicon material is optically transparent. Those skilled in the art would know that other optically transparent materials and other optical wavelengths can be used and the device dimensions example used to illustrate the laser operations at 1550 nm wavelength range can be converted to equivalent dimensions when other materials and other optical wavelengths are used. Usually, the required physical dimensions of the devices involved are linearly proportional to the wavelength and linearly inversely proportional to the optical refractive index of the materials used, as is well known to those skilled in the art.

Furthermore, for the purpose of illustration and not limitation, the exemplary OTFT platform by using III-V semiconductor (e.g., Indium Phosphide (InP) or Indium Gallium Arsenide Phosphide (InGaAsP) as the active materials (e.g., to provide the optical gain needed to achieve lasing) will be described. Those skilled in the art would know that many other semiconductor-based materials (or optical gain materials that are not semiconductors) can also be used as the active optical materials. Thus, while the various exemplary embodiments described below use silicon, SOI, and III-V semiconductors for illustration purpose to illustrate the device structures in the embodiments, they are not meant to limit the invention, unless specifically specified. Many other materials can be used as long as they serve the same functional purposes for example, to provide the optical transparency, the optical gain, or the required refractive indices or the refractive-index differences, as is well known to those skilled in the art.

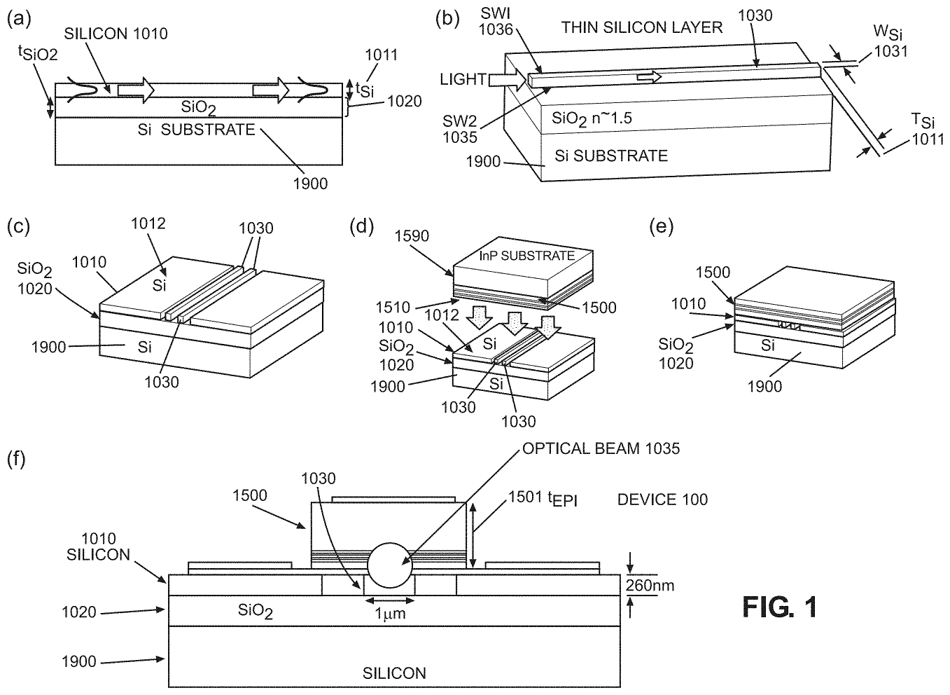

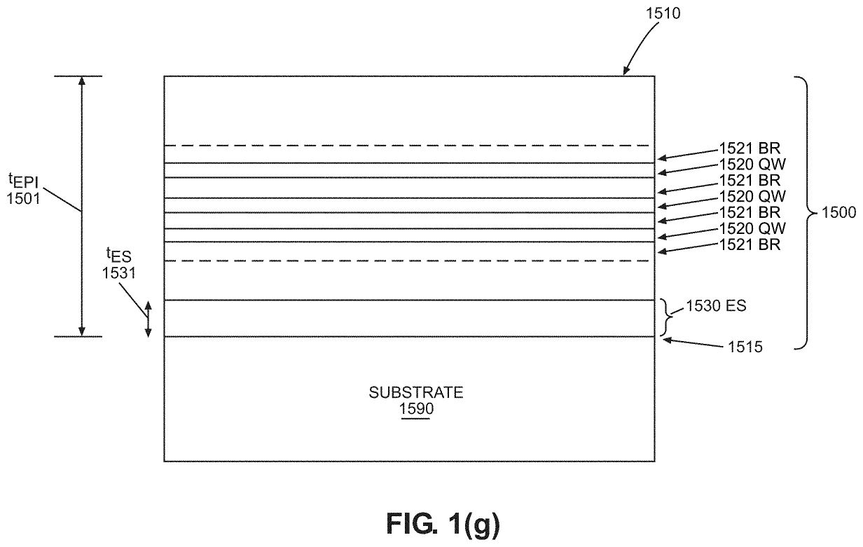

With the above in mind, an exemplary embodiment of the OTFT platform is shown in FIG. 1(a) illustrating an OTFT-platform based Device 1000, for which the passive optical devices are fabricated on a substrate 1900 using a top silicon layer of a silicon-on-insulator (SOI) wafer. Layer 1010 has a thickness t_{Si} 1011. This top silicon layer can be used as the waveguiding core for the passive device as silicon has a high refractive index of n˜3.47 and is transparent at 1550 nm. Below the silicon layer is a low-refractive-index (n˜1.45) buried silicon dioxide layer 1020 with thickness t_{SiO2} 1021, forming the lower waveguide cladding so the waveguide is strongly guiding vertically (see FIG. 1(a)). As an exemplary embodiment t_{SiO2} 1021 is 1-2 microns thick. SOI is a common type of semiconductor wafer used for silicon-photonics to realize passive optical devices, as is well known to those skilled in the art. In general, wafers made of other materials can be used as long as there is a thin layer of optical waveguiding material acting as layer 1010 on a substrate 1900 that is surrounded below by material of a lower refractive index acting as layer 1020. Such other materials can include, but are not limited to, InP, GaAs, LiNbO3, transparent dielectric materials such as, but not limited to, SiO2 and Si3N4, polymers such as, but not limited to, B-staged bisbenzocyclobutene and polymethyl methacrylate, and combinations thereof.

To form an active waveguide with optical gain, the silicon layer is first etched down in direction perpendicular to the plane of the substrate 1900 to form a waveguide 1030 with waveguide width w_{Si} 1031 and waveguide thickness (or height) t_{Si} 1011 as shown in FIG. 1(b). When the side wall SW1 1035 and side wall SW2 1036 are playing a significant role in guiding the optical beam (i.e., there is substantial optical energy of the optical beam at the side wall), the waveguide is referred to as “channel waveguide”. If the width w_{Si} 1031 is much wider (typically much wider than the thickness t_{Si} 1011) such that side wall SW1 1035 and side wall SW2 1036 are not playing a significant role in guiding the optical beam, the waveguide is referred to as “planar waveguide.” For example, the beam will be confined mainly in the vertical direction and is freely expanding, contracting, or propagating in the horizontal direction. The description of a waveguide being a “channel” or a “planar” waveguide is to convey the abovementioned two situations. Often though, the term “channel” or “planar” waveguide as a descriptive term can be used interchangeable without significant material difference unless otherwise specifically specified.

For a typical OTFT-Platform device, passive silicon waveguides 1030, diffraction grating (not shown), and other passive devices (not shown) are first fabricated on the silicon layer as illustrated by FIG. 1(c). An epitaxial layer structure 1500 is then grown on another substrate 1590 by a material growth machine, such as MOCVD (Metal Organic Chemical Vapor Deposition) or MBE (Molecular Beam Expitaxy) machine or the like as are known to those skilled in the art. In an exemplary embodiment, the substrate 1590 is Indium Phosphide (InP).

A typical epitaxial layer structure 1500 is shown in FIG. 1(g). It is a thin layer of material grown on substrate 1590. The layer structure has a thickness t_{EPI} 1501 and a top surface 1510 after the material growth. It also has a bottom interface 1515 with the substrate. In an exemplary embodiment, there are one or more quantum wells shown as QW 1520 within the structure 1500. To form quantum wells, as is known to those skilled in the art, each quantum well QW 1520 is surrounded by barrier material BR 1521. In an exemplary embodiment, the quantum wells QW 1520 are made of InGaAsP based materials that have smaller energy bandgaps than InP material, and these InGaAsP quantum wells are sandwiched (or surrounded) by InP barrier material. Furthermore, in an exemplary embodiment, the epitaxial layer structure will have N-doped or P-doped regions to form one or more PN junction to inject carriers into the active material region such as the quantum wells described above.

In another embodiment, as illustrated by FIG. 1(g), at the bottom interface 1515 of the epitaxial layer structure 1510 is grown a selective etch-stop layer ES 1530. In one embodiment, ES 1530 is a thin layer InGaAsP material with thickness t_{ES} 1531. As discussed below, a purpose of the etch-stop layer is to enable one to etch away and remove the substrate 1590 material using a wet (e.g., via a chemical solution) or dry (e.g., via reactive-ion-etching or RIE) etching method without touching (i.e., without etching) the epitaxial layer structure 1500. For example, InP substrate can be etched away at a high rate using HCl (Hydrochloric acid) etchant but HCl will not etch InGaAsP much (i.e., its etching rate with InGaAsP material is much slower than that with InP material), and the etching of InP by HCl will self-stop at the bottom interface 1515 without touching the epitaxial layer structure 1500.

As shown in FIG. 1(d), the top surface 1510 of the epitaxial layer structure 1500 is then turned up-side down and pressed against the silicon surface 1012 that has been pre-etched with passive devices including waveguides 1030. In one exemplary embodiment, as is known for those skilled in the art, a wafer-bonding process involving certain surface chemical treatment followed by applying a certain pressure and thermal cycling then enables the InP surface and silicon surface on both sides of the contacted area to be bonded together. In another exemplary embodiment, as is known to those skilled in the art, a bonding material such as BCB (benzocyclobuten) polymer or other polymers, glass or other dielectrics, or metal is used between surface 1510 and surface 1012 (applied to one or both of these two surfaces before they are pressed together) to bond surface 1510 to surface 1012. After the bonding, the InP substrate 1590 with the epitaxial layer structure 1500, would sit at one side of the bonded area. A wet or dry selective etching method such as that described above is then used to remove the InP substrate. The etching would self-stop at interface 1515. This leaves the 1510 side of the epitaxial layer structure 1500 bonded to the top silicon surface 1012, as shown by FIG. 1(e).

In an exemplary embodiment, after the wafer bonding and transfer of the epitaxial layer structure 1500 onto the silicon surface 1012, the structure 1500 is further patterned by photoresist and photolithography (or electron-beam (Ebeam) resists and Ebeam lithography) or the like, and then further fabricated into device structures via etching and other fabrication processes. As an exemplary embodiment, FIG. 1(f) shows an exemplary resulted structure showing that the epitaxial layer structure 1500 is etched on both sides after the bonding of the epitaxial layer 1500 with a silicon channel waveguide 1030 below. An optical beam 1035 is shown propagating partly by the silicon waveguide structure 1030 and partly by epitaxial layer structure 1500. The optical beam 1035 can be transferred between the optical gain layer with quantum wells (part of the epitaxial layer structure 1500) and the silicon waveguide beneath it using an integrated vertical mode coupler, typically in the form of horizontal tapering waveguide with one or more tapering teeth on the silicon layer or on the gain layer, or on both layers. Note that in referring to “top or bottom” and “up or down”, typically the substrate side is the “bottom side” or “down”.

An Exemplary Embodiment of a Device of the Present Invention Showing an Exemplary Geometry of a Laser System Integrated on a Chip

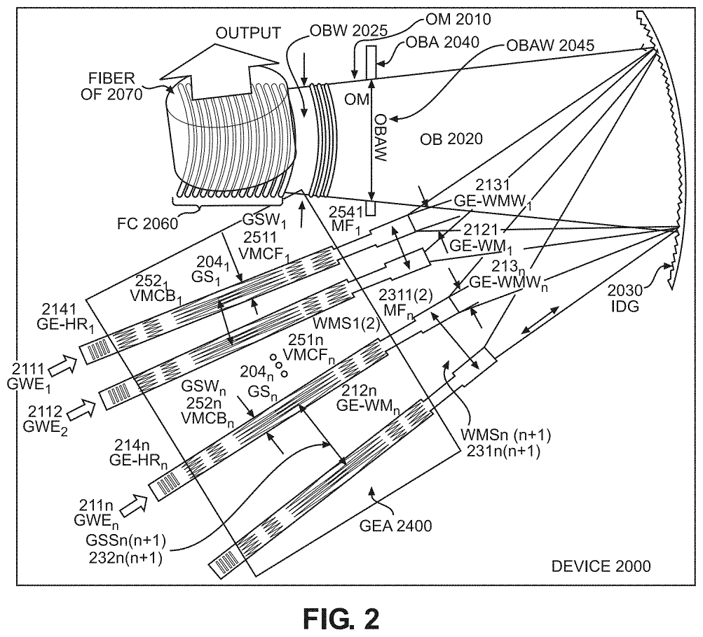

For the purpose of illustration and not limitation, an exemplary geometry for the present invention is shown in FIG. 2 referred to as Device 2000 In the description below, the three-dimensional structure of the present invention is based on the OTFT platform described above. Thus, the description below will describe mainly the top-view geometry while referencing the general OTFT platform for its detail three-dimensional structure. As noted in the introduction, the present invention will enable the realization of efficient integrated lasers that are capable of various functionalities, including providing high lasing power output.

As an exemplary embodiment of the present invention utilizing the OTFT platform of FIG. 1, a passive waveguiding layer is the top silicon layer 1010 of a silicon-on-insulator (SOI) wafer, as shown by FIG. 1(a). The high-refractive-index silicon with refractive index n˜3.47 in layer 1010 provides wave confinement in direction perpendicular to the substrate (called the “vertical direction” below), and forms a waveguide of thickness t_{Si} 1011. If the silicon layer is further etched down on both sides to form a channel of width w_{Si} 1031, it becomes a channel optical waveguide, like the structure shown in FIG. 1(b). After the etching, as an option, the channel waveguide may be further deposited and covered with low-refractive index material such as silicon dioxide in some areas of the waveguide as an upper waveguide cladding or it may not be covered at all (e.g., it may be bonded with the active gain material or may be left as air). For the purpose of illustration and not limitation, for operating at 1550 nm wavelength range, this silicon waveguiding layer 1010 is 200-1000 nm thick and is on top of a 1-micron thick thermal silicon dioxide layer 1020 (called the buried oxide, BOX).

As an exemplary embodiment, assuming the silicon layer is surrounded by silicon dioxide (n˜1.5), silicon nitride (n˜2), or aluminum nitride (AlN; n˜2.1) as the waveguide cladding materials, such waveguide would be considered a strongly-confined or high-refractive-index contrast waveguide. In addition, the use of AlN is particularly conducive for high-power laser applications as it has very high thermal conductivity close to that of metal and has been shown to be a good material for integrated optic devices at 1550 nm wavelength range.

As an exemplary embodiment, for application at the 1550 nm wavelength range, a 500 nm thick t_{Si} 1011 for the silicon layer 1010 shown in FIG. 1(a) would give a near single-mode planar optical waveguide in the vertical direction with two well-confined optical modes (in the vertical direction), namely the symmetric first-order fundamental guiding mode that is the lowest-order mode, and an anti-symmetric second order guiding mode. A 1000 nm thickness for t_{Si} 1011 would basically give 4 modes in the vertical direction that can guide. Thus, a thicker waveguide thickness will result in “multimode waveguiding” and not “single-mode waveguiding” in the vertical direction, as is known to those skilled in the art. While single-mode waveguiding is typically desirable, a large silicon-layer thickness would enable the beam intensity to be lower or the beam power to reach a higher value before causing excessive nonlinear optical absorption that can lead to material damage. Thus, for achieving high-power lasing, as an exemplary embodiment, a 200 nm-1000 nm thickness for the silicon waveguiding layer can be used.

Thus, as discussed above, at 1550 nm wavelength range, when the silicon waveguide thickness is thicker than about 300 nm, a few vertical modes can be guided. However, it turns out that waveguide with a few modes can be made to guide mainly in the first-order mode using various techniques, including a “mode filter” to be described below that would cause high loss for the higher-order modes and hence can be used to filter out the higher-order modes. With proper mode management, the silicon waveguide thickness could even go thicker than the 1000 nm mentioned above and still make the first-order fundamental mode the dominant guided mode.

The above is exemplary aspect of the passive waveguide thickness that can be used in the present invention that would enable the achievement of higher lasing power. The description of FIG. 2 below will describe in detail the general geometry of the laser cavity structure referred to as Device 2000. This is shown in FIG. 2, which shows the top view of the optical beam paths that are largely guided by the silicon layer 1010 in the vertical direction. As explained below, the beam guiding is in some region guided by planar waveguiding, and in some region by channel waveguiding. The geometry of the laser cavity for exemplary laser Device 2000 shown in FIG. 2 can be understood by following the beam paths: First, a planar-guided optical beam is located near an integrated output reflector referred to as the “output mirror” OM 2010. OM 2010 is a passive device capable of reflecting back part of the energy of a guided optical beam and transmitting part of its energy. OM 2010 is typically in the form of an etched Bragg reflector but can also be in other form such as an etched grating along the sides of guided beam as long as it can reflect the energy of the optical beam back partially and transmitting the energy of the optical beam partially.

An optical beam called the “output beam” OB 2020 near OM 2010 is reflected back from OM 2010 and propagates towards a diffraction grating called the integrated diffraction grating IDG 2030. Note the spatial region occupied by beam OB 2020 is shown in shaded gray and this beam propagates in both directions as shown by the double arrows in the figure (it propagates towards OM 2010 and then reflected from OM 2010 and propagates towards IDG 2030). The beam at OM 2010 has a certain beam width, which would be labelled as OBW 2025 (output-mirror beam width). As an optional embodiment, an output beam aperture OBA 2040 with a width OBAW 2045 is placed just before the output mirror. The width OBAW 2045 is just large enough to pass the output beam width OBW 2025 with minimal loss.

The diffraction grating IDG 2030 then diffracts the beam reflected back from the output mirror OM 2010 towards a gain waveguide element GWE1 2111 if the beam is at wavelength lambda 1 (labelled as “λ1”). If the beam from the output mirror has wavelength “λ2”, then it would be diffracted towards waveguide gain element GWE2 2112. If the beam from the output mirror has wavelength “Xn”, then it would be diffracted towards waveguide gain element GWEn 211n, etc.

Beam propagating towards gain waveguide element 1 GWE1 2111 is first received by a beam-receiving silicon waveguide mouth, called the “gain-element waveguide mouth 1” labelled as GE-WM1 2121. The width of GE-WM1 2121 is labelled as GE-WMW1 2131.

GE-WM1 2121 receives the beam from the grating IDG 2030 and acts as a “slit” for the grating spectrometer. The function of the slit of an optical spectrometer to pass certain spectral bandwidth of the spectrally dispersed beam is well known to those skilled in the art. Such slit is made by an opening of a certain width for the dispersed light beam to pass through referred to as the slit width. In this case, the width GE-WMW1 2131 of the waveguide mouth GE-WM1 2121 functions as the slit width. For the purpose of discussion, GE-WM1 2121 may be called the “exit slit 1” of the grating spectrometer and GE-WMW1 2131 is then the width of exit slit 1. The output beam aperture OBA 2040 may be referred to as the “entrance slit” of the grating spectrometer and OBAW 2045 is the width of the entrance slit. Obviously for the laser cavity with bidirectional propagating beam, the labelling of which slit is the “entrance” or the “exit” slit is a matter of choice. As far as the grating IDG 2030 serving as an optical spectrometer is concerned, it is conventional to think of it as having an entrance beam with a broad optical spectrum that is diffracted to many exit directions, each direction for a particular optical wavelength range. The beam received by GE-WM1 2121 is then guided to a gain waveguide section GS1 2041 that has a bonded epitaxial layer structure like that of layer 1500 in FIG. 1(g) to provide the optical gain. The typical guided mode width and height at this gain waveguide section GS1 2041 are denoted as GS-MDW1 2211 and GS-MDH1 2221, respectively (they are not shown in FIG. 2). At the end of the waveguide element is a high-reflector (highly reflecting mirror) for the optical beam (similar in implementation to that of OM 2010) called the gain-element high-reflector 1 GE-HR1 2141.

In summary, a general wavelength λn from the output mirror OM 2010 would be diffracted by the grating IDG 2030 towards gain waveguide element GWEn 211n with gain-element waveguide mouth GE-WMn 212n. The width of the mouth of this gain-element passive waveguide (e.g., made of silicon layer 1010, in the form of a channel waveguide 1030) is denoted as GE-WMWn 213n. The spacing between two adjacent gain element waveguide mouths, such as for element n and n+1 is denoted by WMSn(n+1) 231n(n+1). It is typical to place the waveguide mouths close to each other forming an array with almost constant adjacent element spacing and, in that case, the gain element waveguide-mouth spacings WMSn(n+1) 231n(n+1) would simply be called WMS 2310 (not shown in FIG. 2). Along gain waveguide element GWEn 211n is a gain section GSn 204n that is made of bonded epitaxial layer structure that can provide optical gain (the gain section is described in detail below). The gain-section area is shown shaded in darker gray in FIG. 2. The guided mode width at this gain section is denoted as GS-MDWn 221n (not shown in FIG. 2). The guided mode height at this gain section is denoted as GS-MDH1 222n (not shown in FIG. 2). The spacing between the gain sections of two adjacent gain elements, such as element n and n+1 is denoted by GSSn(n+1) 232n(n+1) (e.g., between element 1 and 2, this would be labelled as GSS1(2) 2321(2)). It is typical to place the gain sections of the gain elements close to each other in a single “gain element area” (GEA 2400). It is also typical to form an array of gain sections with almost constant spacing and in such case would simply call the gain section spacings GSSn(n+1) 232n(n+1) GSS 2320 (not shown in FIG. 2).

More specifically, light at the waveguide mouth GE-WMn 212n is in the silicon layer (e.g., in layer 1010 of FIG. 1, in the form of a channel waveguide like 1030 of FIG. 1). It is transferred to the optical gain layer at the gain section using a “front” vertical beam coupler (vertical mode coupler front) VMCFn 251n, as described in more detail below. At the end of the gain section propagation, light in the gain layer is transferred back down to the silicon layer of a silicon waveguide using a “back” vertical beam coupler (vertical mode coupler back) VMCBn 252n. At the end of this silicon waveguide is a gain-element high-reflector GE-HRn 214n made on the silicon waveguide. This high reflector is described in more detail below.

The high reflector GE-HRn 214n reflects the beam back to VMCBn 252n, gain section GSn 204n, VMCFn 251n, and towards silicon waveguide mouth GE-WMn 212n. Before the waveguide mouth is a gain-element mode filter MFn 254n that filters out the higher order guided modes and passes basically only the lowest-order fundamental waveguide mode (in the silicon layer). This mode filter is described in detail later. After the mode filter, the beam then exits waveguide mouth GE-WMn 212n and propagates back to the IDG 2030 grating, which subsequently diffracts the beam back to the output beam aperture OBA 2040 and then the output mirror OM 2010. Part of the light at the output mirror OM 2010 is transmitted to a fiber coupler FC 2060 made of surface grating on the silicon planar waveguide. The fiber coupler couples the beam into an optical fiber OF 2070 as output, and is described in detail later. Part of the light at the output mirror OM 2010 is reflected back towards the grating IDG 2030 and forms a closed optical path. The closed path forms an optical cavity with optical gain section GSn 204n providing the needed optical gain to achieve lasing at wavelength λn.

Thus, wavelength λn would lase if gain section GSn 204n is powered up (i.e., applied with electrical current or voltage to achieve optical gain). All the different wavelengths share the common output mirror OM 2010 and the output optical fiber OF 2070.

The gain waveguide elements GWE1 2111 . . . GWEm 211m (assuming a total of m elements) form an array with an array of entrance mouths GE-WM1 2121 . . . GE-WMm 212m.

In one implementation, the gain sections GS1 2041 . . . GSm 204m are placed close to the entrance mouths so the spacing between two adjacent gain section GSS 2320 is about equal to the spacing between adjacent gain-element waveguide mouth WMS 2310 (i.e., WMS˜GSS). This would be the “straight-waveguide connection geometry” (SWGC geometry) shown in FIG. 2. As discussed below, for a given adjacent channel wavelength spacing, the physical size (i.e., the area) of the grating spectrometer is proportional to physical spacing of the gain-element waveguide mouths WMS 2310 that act as its “exit slits”. As the gain section spacing GSS 2320 cannot be too small to achieve high lasing power per gain element that would need the gain section spacing to be large (typically shall be 10 microns or larger), the SWGC geometry would unnecessarily constrain the WMS 2310 to be large (as it has to be equal to GSS 2320), and hence the grating size to be large.

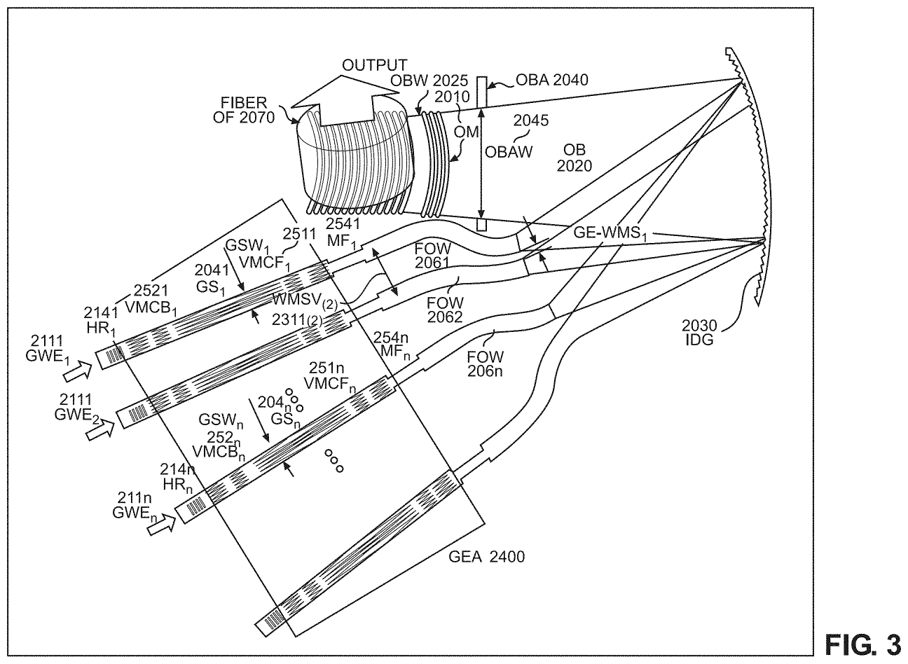

In an alternative implementation shown in FIG. 3, the beam after the waveguide mouth propagating toward the gain section GSn 204n would be channeled via gradual bending of the silicon waveguides that receive the beam so as to enlarge the separation of the silicon waveguides between two adjacent gain elements before connecting the beams to the gain section GSn 204n that would have larger spacing (given by GSS 2320). These waveguides are called “fanning out connecting waveguides” labelled as FOW 206n for the fanning out connecting waveguide for gain waveguide elements GWEn 211n. In this implementation, WMS 2310 is smaller than GSS 2320 (WMS<GSS) so as to result in a smaller grating size (for the same adjacent channel wavelength spacing). This alternative implementation is referred to as “curvilinear-waveguide connection geometry” (CWGC geometry).

Note that the high-reflector GE-HRn 214n at the end of each of the gain element GWEn 211n can be made on the silicon layer 1010 in FIG. 1. The high reflector may, in principle, also be made on the III-V semiconductor gain layer (such as the bonded gain layer 1500 in FIG. 1) that is part of the gain section GSn 204n using optical coating on an etched facet at the end of the gain layer of GSn 204n.

Note that OM 2010 is also called the “wavelength-channel-combined-arm Bragg reflector” as all the different lasing wavelength channels that go through gain sections GS1 2041 . . . GSn 204n, are all combined at OM 2010 to give a single output beam with all the lasing wavelength channel. Note also that GE-WM1 2121 . . . GE-WMm 212m are also called “wavelength-channel-separated waveguide mouths”. Further also note that each of the high-reflector GE-HR1 2141 . . . GE-HRn 214n (at the end of the respective gain waveguide elements GWE1 2111 . . . GWEn 211n) is called a “wavelength-channel-separated-arm Bragg reflector”.

Integrated Diffraction Grating Design

For the purpose of illustration and not limitation, as an exemplary embodiment, herein is described in more detail the integrated diffraction grating IDG 2030. There are various designs desirable for IDG 2030, including the usual Echelle Rowland grating design, and designs that are smaller in size, higher in spectral resolution, or lower in optical loss than the Echelle Rowland grating design. There are also designs with broadband focusing aberration correction enabling high wavelength resolution, high diffraction efficiency, and compact size over a broad spectral bandwidth. Which design to use is dependent on the intended application of the specific IDG-OTFT laser involved. Thus, there is not just one single design but various designs for the grating IDG 2030.

The IDG 2030 can be made on the silicon top layer of a silicon-on-insulator (SOI) wafer such as layer 1010 in FIG. 1. Note that the beam in the grating propagates in a silicon planar (i.e., not channel) waveguide in layer 1010.

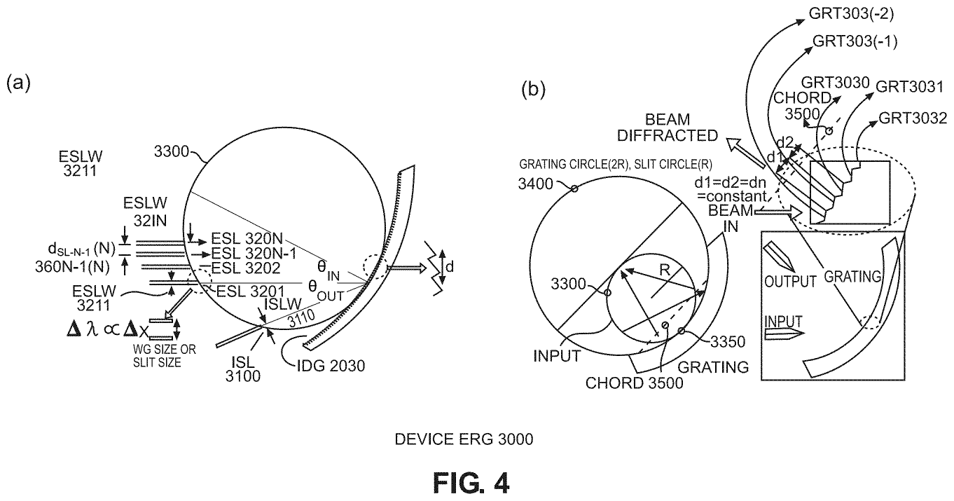

Beside the high resolution, broad bandwidth, and compact size, there are a few key desirable properties for the various designs of grating IDG 2030 that are important specifically for high-power laser applications. To understand that, as shown in FIG. 4, the design of the commonly used Echelle-Rowland curved grating (ER-grating). In ER-grating device ERG3000 shown in FIG. 4, the entrance input slit ISL 3100 (or waveguide) and all the N number of exit slits (or waveguides) labelled as slits ESL 3201 . . . ESL 320N, are placed on a circle 3300 with radius R (see FIGS. 4a and 4b), called the Rowland circle 3300. The grating teeth, however, are placed on a larger circle with radius 2*R, which is called the “grating circle” 3400. This grating circle 3400 is joined with the Rowland circle 3300 at the center of the grating 3350 and are mutually tangential there (see FIG. 4b). The grating teeth, such as 2M+1 grating teeth labelled as the center grating tooth GRT 3030, the teeth to one side (call the “positive” side) GRT 3031, GRT 3032 . . . GRT 303M, and the teeth to the opposite side (call the “negative” side) GRT 303(−1), GRT 303(−2) . . . GRT 303(−M) are generated by placing them along the grating circle 3400 such that they are equally spaced along a chord 3500 of the concave surface 3400, so that d1=d2=d(−1)=(d(−2)= . . . =dM=d(−M) in FIG. 4(b) (only showing d1 and d2, where d1 is the distance between the center of tooth GRT 3030 and tooth GRT 3031, and d1 is the distance between the center of tooth GRT 3031 and tooth GRT 3032, etc.). For a given grating wavelength resolution, the width of the entrance input slit ISLW 3110 and width of the exit slit ESLW 321N, determines the radius 2*R of the grating circle 3400. Let the spacing between two adjacent exit slits, such as slit N−1 and N, be d_{SL-N-1(N+1)} 360N-1(N) determines the channel wavelength spacing. The Rowland curved grating design ensures that a beam from the entrance input slit ISL 3100 diffracted from the grating IDG 2030 would always be well focused onto any of the exit slits ESL 3201 . . . ESL 320N on the Rowland circle 3300. Which exit slit the beam is focused to will depend on the wavelength of the beam.

In the IDG-OTFT laser implementation shown in FIGS. 2 and 3, the equivalent to the “entrance input slit” ISL 3100 is output beam aperture OBA 2040, and the equivalent to the exit slits ESL 3201 . . . ESL 320n are the waveguide mouths GE-WM1 2121 . . . GE-WMn 212n.

The ER-grating design for grating ERG3000 has a few difficulties for high-power integrated laser applications:

The ER-grating design has the property that the physical width of the beam BW 3500 (not shown in FIG. 4) from the entrance input slit (or waveguide) ISL 3100 and the width of the beam BW 360N (not shown in FIG. 4) at the exit slit (or waveguide) ESL 320N are exactly equal. This is a convenient property for many applications but it is not a conducive property for high-power laser applications, especially when many wavelength channels are combined to a single laser output at output mirror OM 2010 to achieve the high optical output power. For the purpose of illustration and not limitation, combining 300 wavelength channels with use of 300 gain elements in laser IDG-OTFT (See FIGS. 2 and 3) to a single output mirror OM 2010, would result in the beam intensity at the laser output mirror OM 2010 being 300 times higher than that at each of the mouths of the gain elements GE-WM1 2121 . . . GE-WMn 212n (assuming they have the same beam width). Note that the output mirror OM 2010 is at the “entrance input slit” formed by the output beam aperture OBA 2040 where OBAW 2045 is the width of the entrance slit of the grating and the n^{th} gain waveguide element GWEn 211n is connected to the n^{th} “exit slit” formed by the width GE-WMWn 213n of the waveguide mouth GE-WMn 212n. To achieve high wavelength resolution, the width of the exit slit GE-WMWn 213n shall be small compared to the optical wavelength used in the device. That means the entrance slit width OBAW 2045 shall also be small in order to match the exit slit width GE-WMWn 213n. However, the narrow slit width at the entrance slit OBA 2040 would then limit the highest power the laser can achieve. Thus, ideally, the entrance slit width OBAW 2045 (or beam size there) should be much wider (for example 10-100 times wider) than the exit slit width GE-WMWn 213n (or beam size there), which cannot be easily done with the ER-grating design.

The exit slits in the ER-grating design have to lie on the Rowland circle 3300. Thus, the waveguide mouths GE-WM1 2121 . . . GE-WMn 212n of the gain waveguide elements GWE1 2111 . . . GWEn 211n are not on a straight line but are on a curved line. This makes it harder to place the gain medium section GS1 2041 . . . GSn 204n at close to the gain-element waveguide mouths GE-WM1 2121 . . . GE-WMn 212n and hence harder to realize the SWGC geometry, which is preferred in some applications as it can minimize the lengths of the connecting silicon waveguides FOW 206n and hence minimize propagation loss. In addition, when the exit slit width is small compared to the optical wavelength used in the device, the large beam divergence angle from the narrow exit slit (formed by the gain-element waveguide mouth GE-WMn 212n) can result in the diverging beam being partly blocked by the adjacent waveguide mouth.

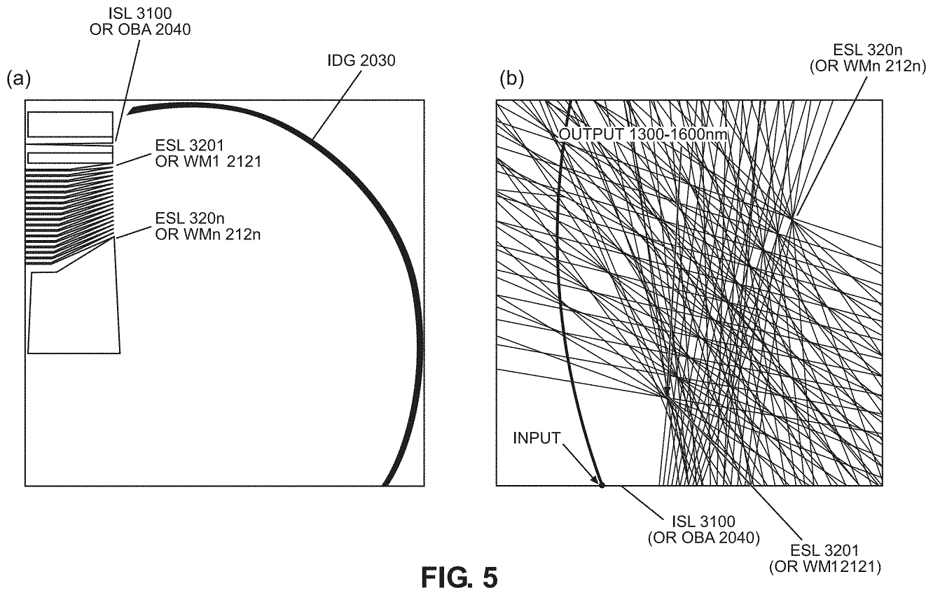

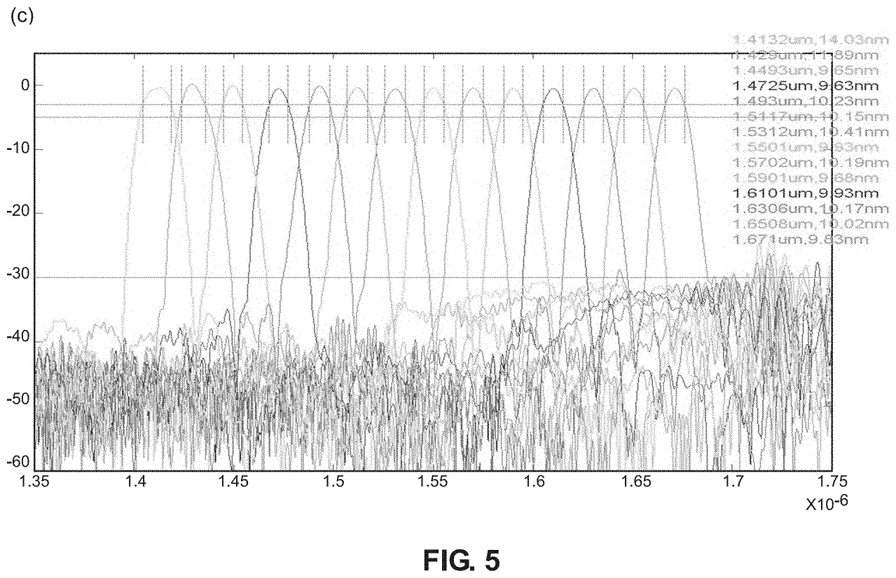

To address the above shortfall for the Echelle grating design for grating IDG 2030, an embodiment of the grating design for grating IDG 2030 uses computationally generated grating that has substantial freedom, referred to collectively as super-compact grating (SCG), to implement the placements of the exit slits formed by the waveguide mouths GE-WM1 2121 . . . GE-WMn 212n. Such computationally generated SCG grating designs are described in the reference patent listed in front referred to as patent: PGR1, PGR2, PGR3, PGR4, PGR5, PGR6, and PGR7, and are hereby incorporated in their entirety. In one aspect of such SCG grating, FIG. 5(a) shows a IDG 2030 grating design in which the exit slits GE-WM1 2121 . . . GE-WMn 212n are placed along a locus that is nearly a straight line, instead of on a circle. This is called the “flat field” design for the exit slit (or waveguide) locations. This flat-field exit-waveguide design also gives maximum beam clearance to enable high spectral resolution that would require large diverging angle for the beams at the narrow exit slits (or waveguide mouths). As noted, it also makes it easier to implement the SWGC geometry. In another aspect of such SCG grating, FIG. 5(b) shows that the rays of the beams at the exit slits GE-WM1 2121 . . . GE-WMn 212n can be designed to be basically aberration-free over a wide 300 nm wavelength range (from 1300 nm to 1600 nm)—(note the relative location (up/down) of the input ISL3100 (or equivalently OBA 2040) in FIG. 5(b) is flipped from that of FIG. 5(a) due to the way the ray figure is generated). In as yet another aspect of such SCG grating, FIG. 5(c) shows the output spectrum of such a grating showing high spectral power rejection for adjacent channels indicating no extra scattering loss due to blockage of beam by adjacent waveguide mouths. It also shows the high spectral performance over the wide 300 nm wavelength range.

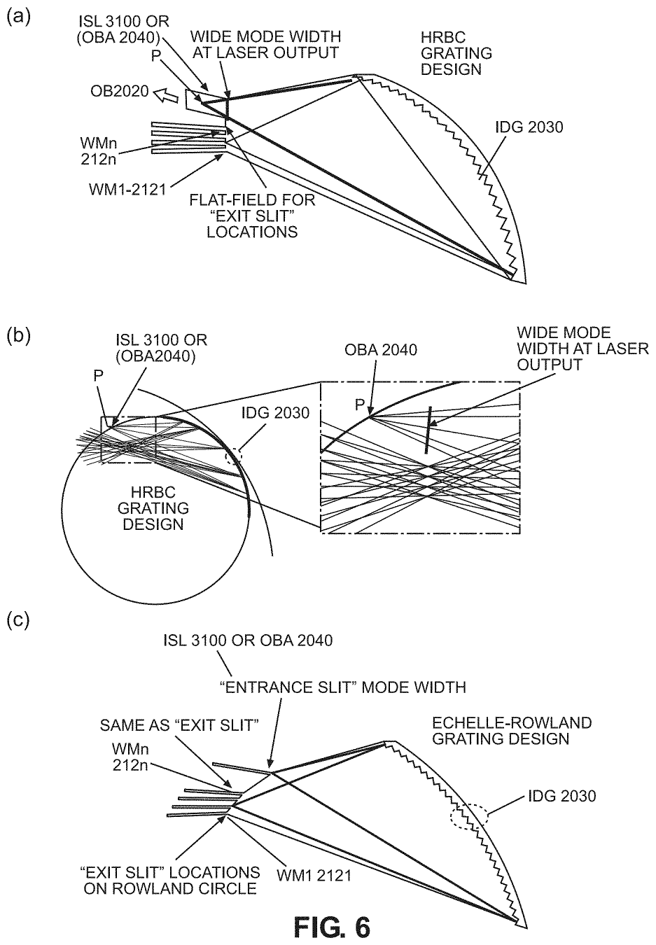

Furthermore, FIG. 6(a) shows that the SCG version of grating IDG 2030 can be designed so that the effective focal point P for the entrance slit OBA 2040 is at a distance away from the grating center that is longer than the distance between the exit slit WMn 212n and the grating center so that the entrance beam would have a wider beam size compared to the beam size at the exit slit WMn 212n. This is a SCG grating generated computationally and the ray diagram for this grating is shown in FIG. 6b. This makes it possible to design the laser output beam OB 2020 to have a beam width 10-100 times or more wider than the widths of the beams at the gain-element waveguide mouths GE-WM1 2121 . . . GE-WMn 212n (see FIG. 6(a)). There is thus a high flexibility to design the on-chip laser beam width at the chip output to the optical fiber.

For example, for the purpose of illustration and not limitation, if the widths of the beams at the gain-element waveguide mouths GE-WM1 2121 . . . GE-WMn 212n are around 5 microns, the width of the output beam can be designed to be 50-400 microns wide to match the mode diameter of multi-mode fibers or it can also be designed to be about 20 microns wide to match the mode size of “large-mode-area” (LMA) single-mode fiber or 8 microns wide to match the mode size of regular single mode fiber. This flexibility makes the use of such grating design to be able to meet a wide variety of possibilities in terms of the maximum power of the laser and the type of optical fiber the output laser light is connected to.

FIG. 6c summarizes the problem of ER-grating design on the width of the entrance and exit slits as well as the exit slits being constrained to be on the Rowland circle, and the laser output beam at the “entrance input slit” ISL 31000 (or equivalently OBA 2040) can only be of the same width as the beams at the “exit slits” GE-WM1 2121 . . . GE-WMn 212n.

Note that in the laser application shown by FIGS. 2 and 3, part of the optical-gain section waveguides are transparent silicon channel waveguides (like 1030 in FIG. 1(b) or (c)) At part of the optical-gain section, these transparent silicon channel waveguides are joined with the InP based optical gain layer bonded on top of the waveguides (like 1500 on 1030 in FIG. 1(f)) to provide optical gain. The grating region is planar waveguide so the light is confined in the silicon guiding layer 1010 in the vertical direction. The linear propagating loss in such silicon planar waveguiding region can be very low (<0.1 dB/cm). For the purpose of illustration and not limitation, as an example, the propagating length (˜1-4 cm) of the lasing beams in the chip is in this “passive planar waveguiding” region. The grating IDG 2030 is formed by vertically etching down into the silicon guiding layer 1010.

Exemplary Gain Medium Structure

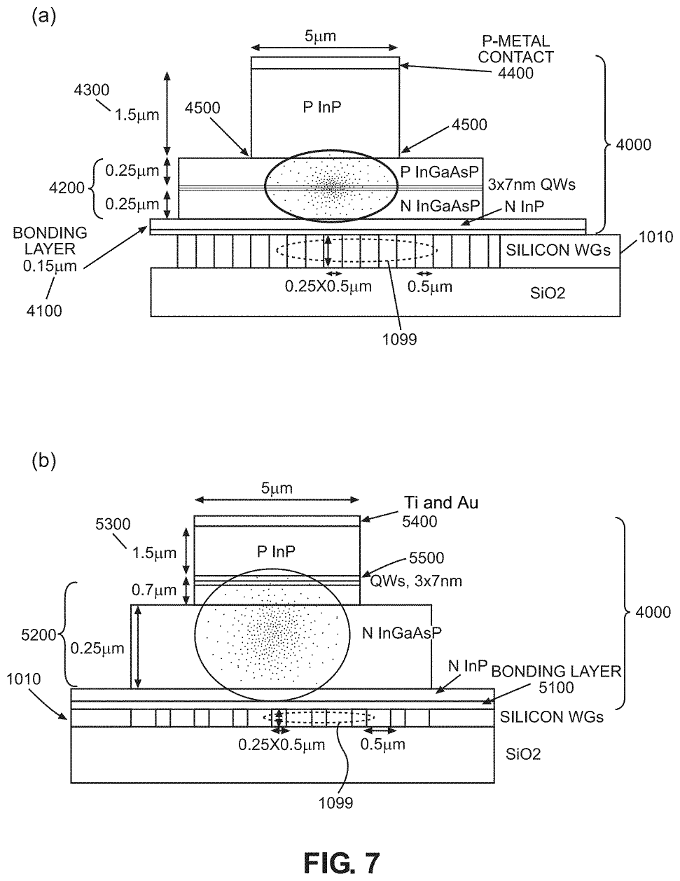

For the purpose of illustration and not limitation, two exemplary gain medium structures are illustrated for operation at the 1550 nm optical wavelength range, which is called the regular-mode-size (RMS) structure 4000 and the large-mode-size (LMS) structure 5000 as shown in FIGS. 7a and 7b, respectively, showing the epitaxial layer structure after it is transferred and bonded to the silicon surface of a SOI wafer.

For the RMS structure 4000 shown in FIG. 7a, as an exemplary embodiment, for the purpose of illustration and not limitation, the lowest layer 4100 bonded to silicon surface 1012 is a 200 nm-thick N⁺-doped InP layer 4100. This is followed by a 500 nm-thick undoped waveguide core layer 4200 with an optical gain medium (e.g., the gain medium can be provided by a few quantum wells or other optical gain medium as is known to those skilled in the art). Above the waveguide core layer 4200 would be an around 1.5-micron thick P-doped InP top cladding layer 4300 followed by a 100 nm-thick P⁺-doped InGaAs metal Ohmic-contact layer 4400. The top cladding layer 4300 is etched to form a waveguide rib structure 4500 enabling a ˜4 micron-wide horizontal mode size for the guided optical mode that would have low loss for the first-order fundamental waveguide mode. The vertical mode size is defined by the 500 nm-thick core and would have a mode size of around 500 nm.

For the purpose of illustration and not limitation, for the LMS structure 5000 shown in FIG. 7b, as an exemplary embodiment, for the purpose of illustration and not limitation, the lowest layer bonded to silicon is a 200 nm-thick N⁺-doped InP layer 5100. The InP layer has a refractive index of around n=3.17 at 1550 nm wavelength. For the purpose of illustration and not limitation, this is followed by a 3900 nm-thick InGaAsP material giving a large lightly N-doped waveguide core 5200 with refractive index n=3.22 that is just slightly higher than the refractive index of InP (n=3.17). This would enable a large vertical mode size close to 4 microns. Above the waveguide core layer would be a 1.5-micron thick p-doped top cladding layer 5300 followed by a 100 nm-thick P⁺-doped InGaAs metal Ohmic-contact layer 5400. The top cladding layer 5300 would be etched to form a waveguide rib structure 5500 enabling a ˜4 micron-wide horizontal mode size that would also have low loss for only the first-order fundamental waveguide mode (in the horizontal direction).

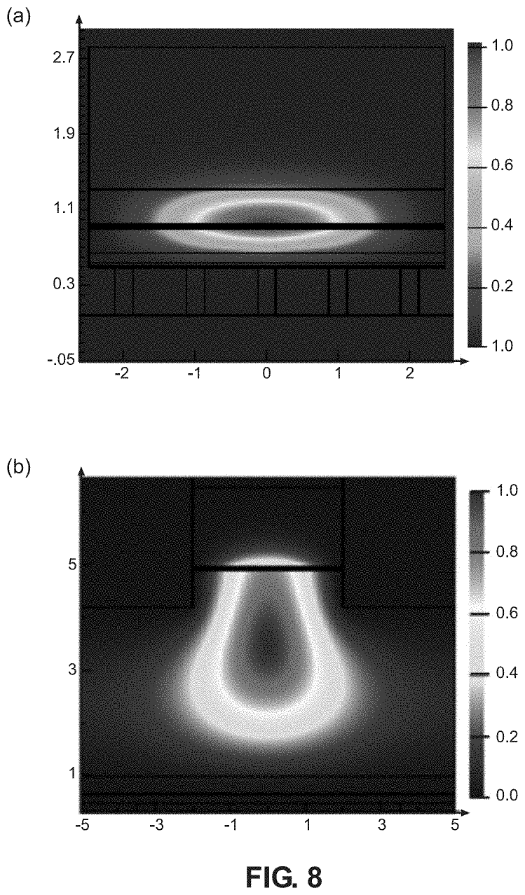

Thus, both the RMS 4000 and LMS 5000 structures are designed so that only the lowest order mode would have low loss and would be the one to achieve lasing. In an exemplary embodiment, as an option, below the bottom N-doped layer is an array of narrow silicon structures 1099 formed by etching down the top silicon layer 1010 of the SOI wafer, each having a width narrower than 250 nm and spaced by 500 nm center-to-center. This array is to lower the effective refractive index of the silicon layer so the mode will be more pushed up into the structure 4000 or 5000 that would have higher averaged refractive index. Note that the silicon-layer etching is done before the InP epitaxial layer wafer bonding. This silicon structure has an “effective propagating refractive index” lower than the refractive index of InP and would not be penetrated much by the optical mode. FIGS. 8a and 8b show the simulated fundamental waveguiding mode for the RMS structure 4000 and LMS structure 5000, respectively.

Exemplary Vertical Coupler Design

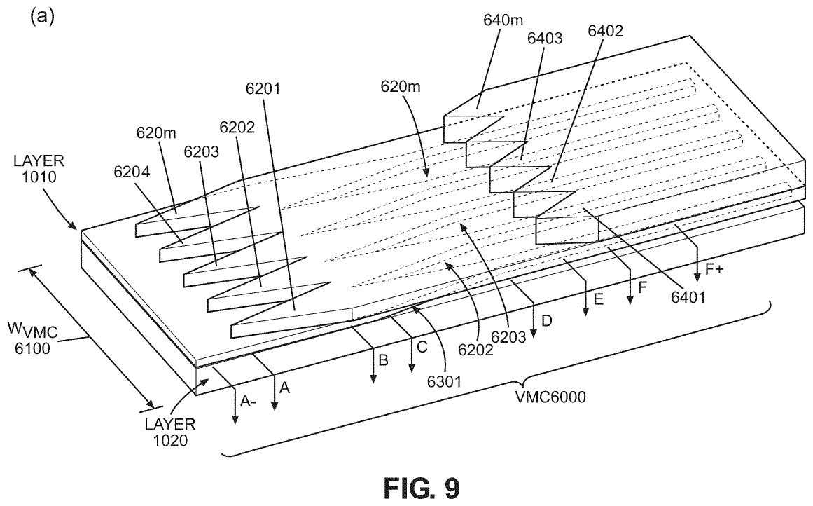

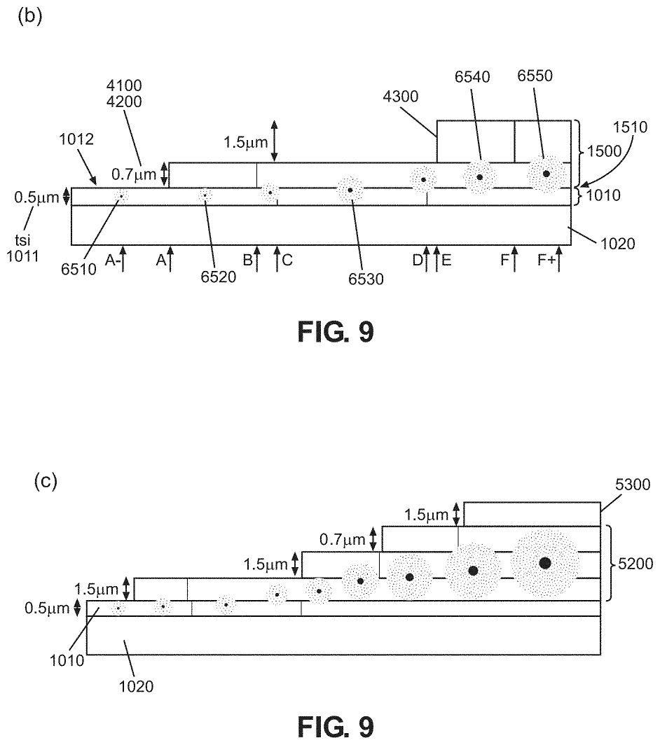

As noted in FIGS. 2 and 3, the beam entering gain-element waveguide mouth GE-WMn 212n with width GE-WMWn 213n is transferred to the active gain layer via a vertical mode coupler at the “front” (VMCFn 251n) and then transferred back to the silicon layer again with another vertical mode coupler at the “back” (VMCBn 252n). They (i.e., VMCFn 251n and VMCBn 252n) can be made of the same structure or different structures. Possible structures of VMCFn 251n or VMCBn 252n are referred to as Vertical Mode Coupler VMC 6000 in FIG. 9.

For the purpose of illustration and not limitation, a vertical mode coupler VMC 6000 is shown in FIG. 9 illustrating the case of a 5-micron wide silicon waveguide as the gain-element waveguide mouth with width W_{VMC} 6100 equal to 5 microns. In an exemplary embodiment, W_{VMC} 2590 is about equal to GE-WMWn 213n. For the purpose of discussions, the thickness of the silicon waveguide t_{Si} 1011 is taken to be 500 nm (or 0.5 um, i.e., 0.5 micrometer). The case of a RMS optical-gain structure 4000 with 700 nm (or 0.7 um, i.e., 0.7 micrometer) thick waveguiding layer is assumed to be made up of layer 4100 plus layer 4200 (See FIG. 7a-responsible for waveguiding on top of the silicon). The function of the vertical coupler is that by etching an array of horizontal tapering teeth into the waveguide layer, the effective index of that layer is lowered, enabling the optical beam to be pushed away from that layer. It acts like a vertical physical taper that connects mode from a vertically wider waveguide into a vertically narrower waveguide or vice versa. As an example, for the purpose of illustration and not limitation, a first set of tapering teeth can be made on the 5-micron wide and 700 nm thick active layer (made up of the 500 nm-thick core layer 4200 and the 200 nm-thick lower cladding layer 4100, which is the part of active layer 1500 in FIG. 1 next to the bonded interface 1510 with silicon surface 1012). In this example, it forms into an array of 5 tapering teeth (spaced by 1 micron center-to-center), labelled as tooth 6201, 6202, 6203, 6204, 6205 (in general, if there are “m” teeth, they will be 6201 . . . 620m), with each tooth tapering up from below 0.2 micron in width at point A to 1 micron in width at point B (see FIG. 9a). For the purpose of illustration and not limitation, the distance between point A to B can be around 10-100 microns. The taper enables the mode to expand from silicon to occupy the silicon layer plus part of lower cladding layer (layer 4200) and the core layer (layer 4200) of the RMS structure 4000. At this region (from point A to point B), the mode energy still remains mainly in silicon as silicon has high refractive index.

For the purpose of illustration and not limitation, a second array of 5 “down-tapering” teeth, labelled as tooth 6301, 6302, 6303, 6304, 6305, are made in the silicon layer 1010, with each tooth tapering down from about 1 micron in width at point C to below 300 nm in width at point D (It may not be very clear from the 3D figure, these teeth 6301, 6302, 6303, 6304, 6305 are actually on the silicon layer 1010 that is below the layer (layer 4100+4200 for 6301, 6302, 6303, 6304, 6305—in the figure layer 4100+4200 are made translucent). For the purpose of illustration and not limitation, the distance between point C to D shall be around 20-300 microns. In this example for the purpose of illustration and not limitation, this “down-tapering” teeth structure enables the mode to be pushed up from the silicon layer 1010 into the 700 nm-thick layer (layer 4100+4200) containing the waveguide core. The evolution of the beam mode is illustrated schematically in FIG. 9b, which shows the structure with tapering teeth from the side view. The “circular dots” of different sizes, labeled as 6510, 6520, 6530, 6540, 6550, represent the modes sizes at different sections of the tapering structure 6000 utilizing RMS 4000 as the gain-layer structure.

For the purpose of illustration and not limitation, the 1500 nm-thick top cladding layer 4300 of structure RMS 4000 shown in FIG. 9(a) also forms into an array of 5 tapering teeth, labelled as tooth 6401, 6402, 6403, 6404, 6405, and as an example with each tooth tapering up from below 0.2 micron in width at point E to 1 micron in width at point F. For the purpose of illustration and not limitation, the distance between point E to F shall be around 20-300 microns. This tapering teeth structure enables the upper part of the mode to be pushed up slightly into the 1500 nm-thick top cladding layer 4300.

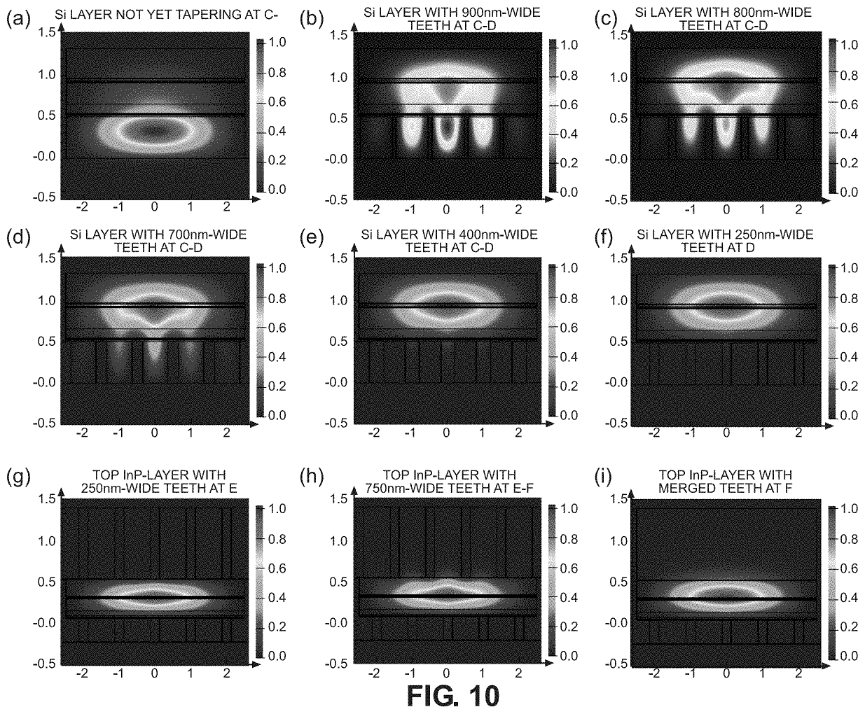

For the purpose of illustration and not limitation, the simulated modes at different points for the case of the vertical coupling from silicon waveguide to the RMS (regular core) structure 4000 of FIG. 7a are shown in FIG. 10.

FIG. 10(a) shows the simulated mode at point B of FIGS. 9(a) and (b). FIG. 10(b) shows the simulated mode at point C-D of FIGS. 9(a) and (b) with the example width of silicon down-tapering teeth 630m mentioned above being 900 nm wide. FIG. 10(c) shows the simulated mode at point C-D of FIGS. 9(a) and (b) with the example width of silicon down-tapering teeth 630m mentioned above being 800 nm wide. FIG. 10(d) shows the simulated mode at point C-D of FIGS. 9(a) and (b) with the example width of silicon down-tapering teeth 630m mentioned above being 700 nm wide. FIG. 10(e) shows the simulated mode at point C-D of FIGS. 9(a) and (b) with the example width of silicon down-tapering teeth 630m mentioned above being 400 nm wide. FIG. 10(f) shows the simulated mode at point D of FIGS. 9(a) and (b) with the example width of silicon down-tapering teeth 630m mentioned above being 250 nm wide.

FIG. 10(g) shows the simulated mode at point E-F of FIGS. 9(a) and (b) with the example width of teeth 640m (up-tapering teeth on layer 4300) mentioned above being 250 nm wide. FIG. 10(h) shows the simulated mode at point E-F of FIGS. 9(a) and (b) with the example width of teeth 640m (up-tapering teeth on layer 4300) mentioned above being 750 nm wide. FIG. 10(i) shows the simulated mode at point E-F of FIGS. 9(a) and (b) with the example width of teeth 640m (up-tapering teeth on layer 4300) mentioned above being 1,000 nm wide (i.e., the teeth are merged together and the teeth disappear).

Thus, from FIG. 10, it can be seen that the main mode transformation occurs at section C-D of FIG. 9a as illustrated by the significant mode change from FIG. 10a to FIG. 10e, showing the mode being moved from the silicon waveguide layer to the 500 nm-thick waveguiding core of the InP based epitaxial layer structure with quantum wells.

For the purpose of illustration and not limitation, in the case of the LMS structure 5000 of FIG. 7b with 4-micron large vertical mode size, one would need to enlarge the mode via more sections of the tapering-teeth structure, each section changing the mode size by about 1 micron. A schematic for the mode transformation in the LMS structure 5000 is illustrated by FIG. 9c.

Exemplary High-Reflector Structure

For the purpose of illustration and not limitation, the high reflector GE-HRn 214n (see FIGS. 2 and 3) required at the end of each of the gain elements, is made on silicon.

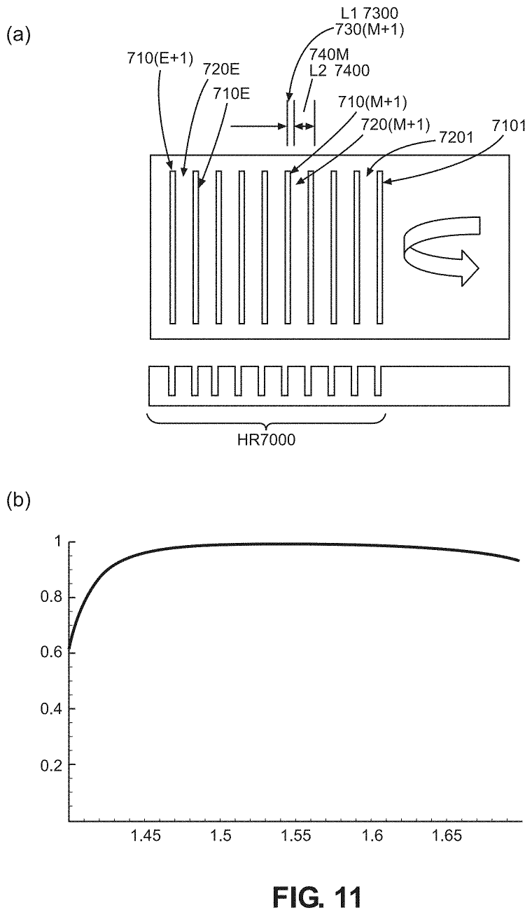

There are various possible structures for high reflector GE-HRn 214n. Possible structures of GE-HRn 214n will be referred to as High-Reflector HR 7000 in FIG. 11. As an example, for the purpose of illustration and not limitation, HR 7000 is made of a Bragg grating formed by etching periodic holes into the silicon waveguide layer. As an example for the purpose of illustration and not limitation, the etched holes are deposited with transparent dielectric materials such as silicon dioxide, silicon nitride, or aluminum nitride. Alternatively, they can be left as air holes. The etched holes are labeled by hole 7101, 7102, . . . 710M, 710(M+1) . . . 710(E+1), and their respective hole widths by 7301, 7302, . . . 730M, 730(M+1) . . . 730(E+1), where M and E are integers, and E+1 labels the last hole. The unetched solid sections between the two adjacent holes are labeled by section 7201, 7202, . . . 720M, 720(M+1) . . . 720(E), and their respective section widths (i.e., each width is defined by the distance between the nearest edges of two adjacent holes) by 7401, 7402, . . . 740M, 740(M+1) . . . 740(E), where M and E are integers, and E labels the last solid section.

In general, the lengths (7301, 7302, . . . 730M, 730(M+1) . . . 730(E+1)) of the etched holes can be all different or the same. In general, the lengths (7401, 7402, . . . 740M, 740(M+1) . . . 740(E)) of the solid sections can also be all different or the same. However, it is typical in a design to choose the lengths for the holes to be all the same and the lengths for the solid sections to be all the same. In that can, one can label the length of the etched down region (i.e., the holes) to be L1 7300 with propagating refractive index n1 7350 (called the low-refractive-index grating tooth) and the length of the solid section (unetched down section) to be L2 7400 with propagating refractive index n2 7450 (called the high-refractive-index grating tooth).

For the purpose of illustration and not limitation, to minimize vertical diffraction loss in the low-refractive-index grating teeth L1 7300 that are etched down, L1 7300 can be shorter than L2 7400 so that: L1=λ/(8 n1) and L2=λ*3/(8 n2) where λ=1550 nm, instead of the usual quarter wave design L1=λ/(4 n1) and L2=λ/(4 n2). By doing so, the vertical diffraction loss can be kept at below 1% for the case of the 500 nm to 1,000 nm thick silicon guiding layer. In another exemplary embodiment, L1 7300 and L2 7400 can be designed as the quarter-wave grating structure with L1=λ/(4 n1) and L2=λ/(4 n2). Those skilled in the art would know that there are various ways to design the Bragg grating structures, and most of them can be used as long as they can provide the reflection and transmission required for function as GE-HRn 214n.

For the purpose of illustration and not limitation, the vertical cross-section (side view) of this high reflector HR7000 made with 12 periods of L1+L2 is shown in FIG. 11a. The simulated reflection spectrum with 10 periods of L1+L2 is shown in FIG. 11b showing high reflectivity of 99%. The reflecting spectrum is very broadband (>200 nm) due to the high-refractive-index contrast between L1 7300 and L2 7400 grating teeth. Thus, in general, depending on the laser design, the number of teeth in the Bragg reflector is adjected to achieve the reflectivity required for the high reflector HR7000.

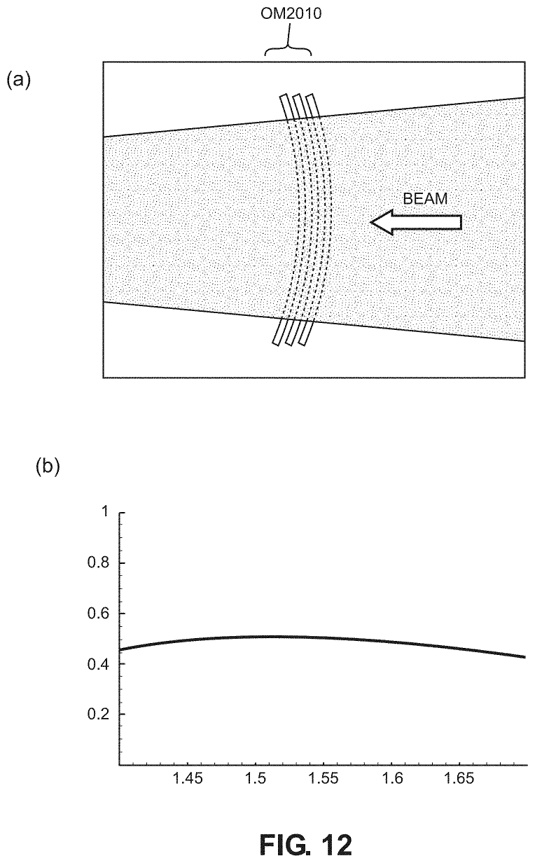

For the purpose of illustration and not limitation, the laser output mirror OM 2010 in FIGS. 2 and 3 is similar to that for the high reflector HR7000 but has curvilinear grating lines horizontally (or surfaces when the hole thickness into the wafer plane is considered) and is shown in FIG. 12a. Another difference is that fewer number of L1+L2 periods is needed. Only 3×L1+L2 periods would give ˜50% power reflectivity over broad bandwidth (>200 nm), which would be sufficient to act as the laser output mirror. Another difference is that the grating, acting as the “output mirror”, could have a wider width than the grating at the gain element that acts as a high reflector so as to match the wider width of the output beam. For the purpose of illustration and not limitation, the grating teeth can be curved so as to match the curved phase front of the converging planar-guided output optical beam. The simulated reflection spectrum with 3 periods of L1+L2 is shown in FIG. 12b. Thus, in general, depending on the laser design, the number of teeth in the Bragg reflector is adjected to achieve the reflectivity required for the output mirror OM 2010.

Exemplary Mode Filter Structure

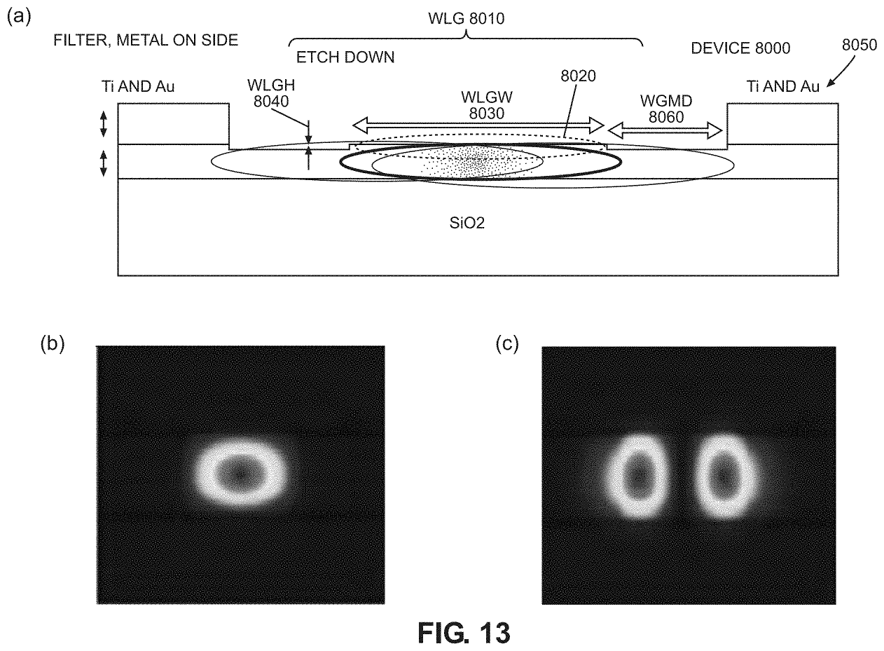

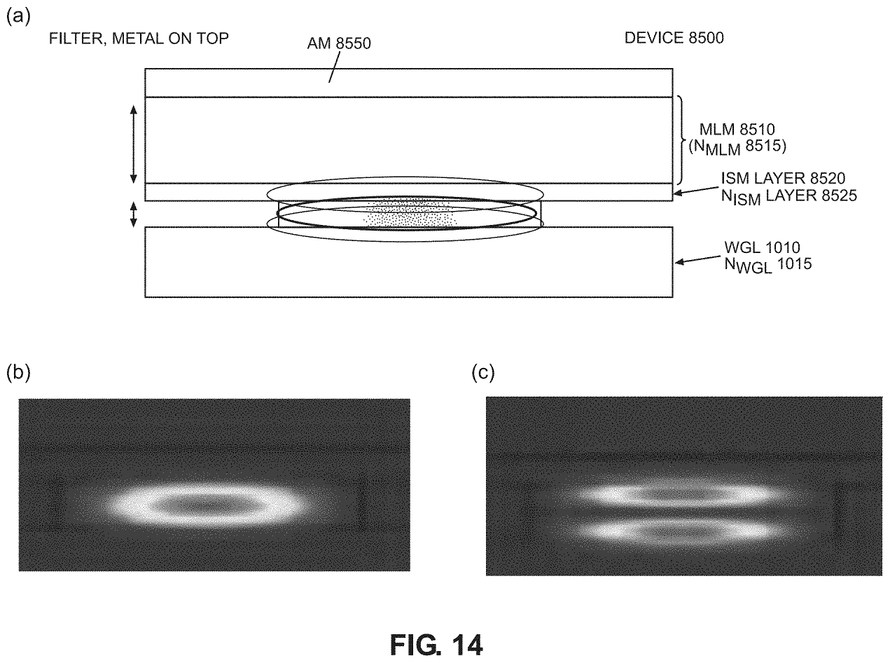

For the purpose of illustration and not limitation, there are two mode filters that can be used in cascade in some cases or each of these two filters can be used by itself: one is the horizontal mode filter Device 8000 shown in FIG. 13, another is the vertical mode filter 8500 shown in FIG. 14. The structure of the horizontal mode filter 8000 shown in FIG. 13a is made of a weakly guiding waveguide WLG 8010. The WLG 8010 is formed by etching a shallow rib structure 8020 with width WLGW 8030 and rib height of WLGH 8040 at the top of the silicon waveguide layer 1010. As an example, for the purpose of illustration and not limitation, the silicon waveguide layer 1010 is 500 nm to 1,000 nm-thick with a rib height WLGH 8040 of around RH=20-50 nm. For the purpose of illustration and not limitation, the value of the width WLGW 8030 is chosen so that the mode width in the weakly guided waveguide WLG section is matching the horizontal mode width of the strongly guiding waveguide it is connected to. For the purpose of illustration and not limitation, on both sides of the rib structure 8020 is deposited with highly optically absorbing Titanium (Ti) metal 8050 on the top surface of the silicon layer 1010. There is a certain waveguide-metal distance WM 8060 between the edge of the rib 8030 to the edge of the metal 8050. This distance may be made the same on both side of the rib or may be made different. The metal may also be on one side of the rib only, instead of two sides. In a typical example, for the purpose of illustration and not limitation, the distances are about the same on both side of the rib and there are metal deposited on both sides, and WM 8060 is approximately 2 micrometres (um).

For the purpose of illustration and not limitation, the first-order fundamental mode has the narrowest horizontal mode width and the second-order or higher modes has wider horizontal mode widths and would incur higher loss due to the Ti metal as they would have higher energy reaching to the Ti metal regions on both side of the WLG rib 8020. For the purpose of illustration and not limitation, the simulation shown by FIG. 13b shows that the absorption loss of the fundamental mode can be low like ˜0.2 dB/mm so that a 0.45 mm long section would only incur 2% loss for the mode, while the horizontal modes of second order and higher would incur over 5 dB/mm loss so that the same 0.45 mm long section would incur more than 40% loss for all the higher-order modes. This would be enough loss differential to ensure only the lowest order horizontal mode would preferentially lase.

For the purpose of illustration and not limitation, the structure of the vertical mode filter 8500 shown in FIG. 14a is made of a layer of “mode-leaking material layer” MLM 8510 with a material reflective index n_{MLM} 8015 placed above the waveguiding layer WLG 1010 that is layer 1010 of FIG. 1 with a material refractive index n_{WGL} 1015 for layer WLG 1010. For illustration purpose and not limitation, an example of layer 8510 is a poly-silicon layer of about 2-micron thick with n_{MLM}˜3.5, deposited on top of a 500 nm to 1,000 nm-thick 1010 waveguide layer WLG 1010 made of silicon with n_{WGL}˜3.5.

As an option, in-between layer 8510 and waveguide 1010, is inserted with an interspaced material ISM 8520 with a material reflective index n_{ISM} 8525. For illustration purpose and not limitation, an example of layer ISM 8520 is a 300 nm thick silicon nitride layer with n_{ISM}˜1.5. The design of layers ISM 8520 and MLM 8520 is to enhance mode energy in waveguide WLG 1010 to be lose to the layer MLM 8520 (by transferring energy to layer MLM 8520) in a way that is high for higher order modes and minimal to negligible for the fundamental waveguide mode in waveguide WLG 1010. This typically requires the index value for n_{MLM} 8525 to be about equal to or higher than index n_{WLG} 1015. Typically, the index n_{ISM} 8525 of the interspaced layer (ISM 8520) is lower than both the value of n_{MLM} 8525 and n_{WLG} 1015. The thickness of the interspaced layer (ISM 8520) is chosen to control the amount of loss so that the higher order modes have high loss while the loss of the fundamental mode is low or negligible.

For the purpose of illustration and not limitation, to further absorb the optical energy that has been transferred (or lost) to the mode-leaking material layer MLM 8510 from the guided mode in waveguide WLG 1010, on top of the layer MLM 8510 is deposited with highly optically absorbing metal AM 8550. As an example for illustration purpose, metal layer AM 8550 is made of Titanium (Ti) that has high optical absorption,

As the vertical first-order fundamental guided mode would have the smallest vertical mode width and the second-order or higher guided modes would have larger vertical mode widths, as is known to those skilled in the art, the second-order or higher modes in waveguide WLG 1010 would couple more energy to the top MLM 8510 layer and hence would incur higher loss of energy to MLM 8510 layer. The energy reaching MLM 8510 layer will be dispersed away in MLM 8510 layer due to propagation side way or scattering loss in MLM 8510 layer. Optionally, the energy reaching MLM 8510 can also be further absorbed by the metal AM 8550.

For the purpose of illustration and not limitation, the simulation shown in FIG. 14b shows that the absorption loss of the vertical fundamental mode can be ˜0.6 dB/mm so that a 0.15 mm long section would only incur 2% loss for the mode, while the vertical modes of second order and higher would incur over 20 dB/mm loss so that the same 0.15 mm long section would incur more than 50% loss for all the higher-order vertical modes. This would be enough loss differential to ensure only the lowest order vertical mode would preferentially lase.

For the purpose of illustration and not limitation, the total length of cascading the horizontal mode filter 8000 of FIG. 13 and the vertical mode filter 8500 of FIG. 14 is 0.6 mm long.

Exemplary Surface-Emitting Grating Fiber Coupler

For the purpose of illustration and not limitation, at the output mirror OM 2010, a part of the beam is transmitted and further propagation from the output mirror OM 2010 to an optical grating fiber coupler FC 2060.

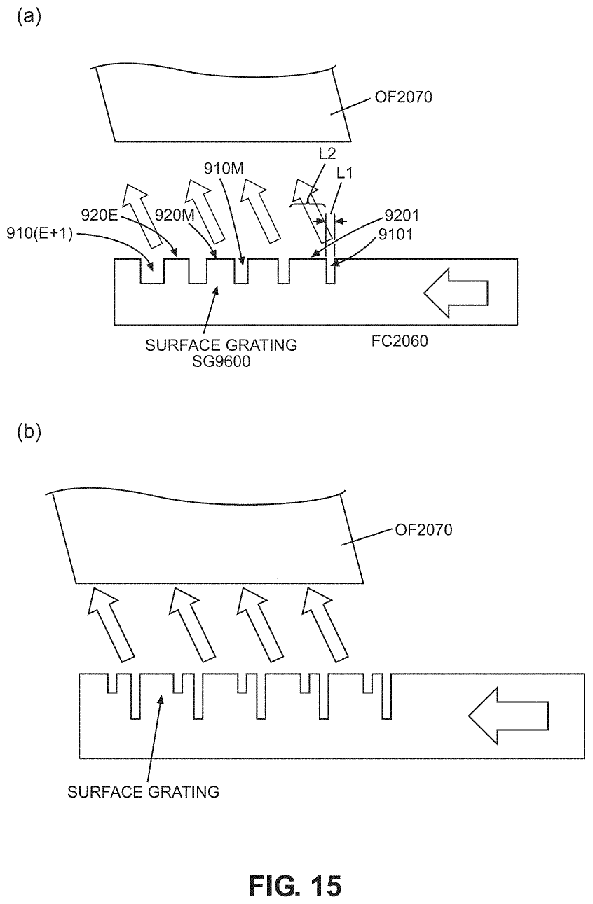

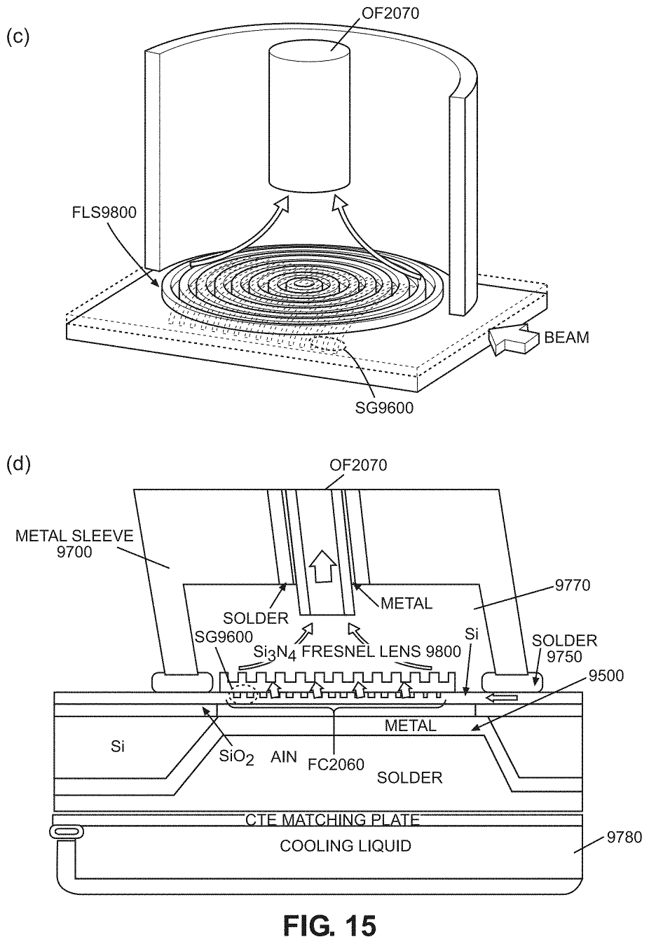

Two main versions for fiber coupler FC 2060 are described below. The first version for FC 2060 is in the form of a surface-emitting grating SG 9600 is shown in FIG. 15a, in which a series of grating teeth is etched into silicon as a series of holes. As an example, for the purpose of illustration and not limitation, the etched holes are deposited with transparent dielectric materials such as silicon dioxide, silicon nitride, or aluminum nitride. Alternatively, they can be left as air holes. The etched holes are labeled by hole 9101, 9102, . . . 910M, 910(M+1) . . . 910(E+1), and their respective hole widths by 9301, 9302, . . . 930M, 930(M+1) . . . 930(E+1), where M and E are integers, and E+1 labels the last hole. The unetched solid sections between the two adjacent holes are labeled by section 9201, 9202, . . . 920M, 920(M+1) . . . 920(E), and their respective section widths (i.e., each width is defined by the distance between the nearest edges of two adjacent holes) by 9401, 9402, . . . 940M, 940(M+1) . . . 940(E), where M and E are integers, and E labels the last solid section.

Serving as an example for illustration purpose but not limitation, the period of these teeth can be near an optical wavelength in the grating layer (instead of half wavelength for reflector). The period is chosen close to an optical wavelength to ensure that the light to emits out of the grating layer (e.g., layer 1010) in the vertical direction (out of the plane of the wafer substrate) towards an optical fiber, instead of reflecting the light energy back within the layer. As is known to those skilled in the art, there are other grating designs that can also emit light in the vertical direction, such example, using two or three times the optical wavelength in the grating layer, which can all be employed for the design of surface grating SG 9600 for fiber coupler FC 2060. An appropriate choice of period would enable the light to be diffracted to be propagating near vertically upward. As the fiber mode is a Gaussian shape, it is preferable that the light diffracted by the grating is also matching the Gaussian shape. For the purpose of illustration and not limitation, one way to do so is to change the duty cycle of the width of L1:L2, where L1 is the length of the etched down region and L2 is the length of the unetched region for the grating. This changing duty cycle for the grating teeth can be employed to tailor the longitudinal mode size and shape to also closely match the fiber mode. One can either follow or modify from this scheme for the grating fiber coupler.

For the purpose of illustration and not limitation, in order to achieve maximum power emission to the top and reduce any power scattering to the bottom part of the chip, as shown by FIG. 15b, one can also alternatively employ a dual-depth design for the alternate teeth of the fiber coupling grating. The interference of light rays scattered from a deep tooth and the adjacent shallower tooth would be in such a way that the rays are destructively interfered for beam propagating toward the bottom direction of the chip, and are constructively interfered for beam propagating toward the top direction of the chip. Using such design, near 90% of the power can be channeled to the top direction and be coupled into the optical fiber efficiently. Etching away the silicon substrate and covering the bottom with a metal reflector spaced by an appropriate distance away from the grating (to enable constructive interference for beam reflected back to the top), would also further increase the emission efficiency. This case with a bottom metal reflector 9500 is illustrated in FIG. 15d. For the purpose of illustration and not limitation, one can typically achieve over 70-80% optical power coupling efficiency for the laser beam from the chip into the optical fiber, for such “surface gating based” optical beam power coupler.

For the purpose of illustration and not limitation, the 1 dB optical bandwidth of the grating fiber coupler can be about as wide as 30-60 nm. For the purpose of illustration and not limitation, the 30-60 nm bandwidth can be achieved by orienting the fiber more towards the normal so that the fiber sustains an angle from the normal of less than or approximately 8 degrees. Wide optical bandwidth will enable higher beam power output for the laser (IDG-OTFT laser).

The desirable width of the output beam is dependent on the type of output fiber to be used. For the purpose of illustration and not limitation, it is typically desirable that the width of the output beam at the grating to be approximately 200 microns if a multimode fiber is used as output fiber OF 2070, as the mode diameter of a multi-mode fiber can be as large as 200 microns. On the other hand, it is desirable that the width of the output beam at the grating be about 8 microns or 20 microns if a regular single mode fiber is used or a large-mode-area (LMA) single-mode fiber is used. This is because the mode diameter of a regular single mode fiber is 8 micron and that of a large-mode-area (LMA) single-mode fiber can be around 20 microns.

The beam width at the output mirror OM 2010 is denoted by BW_{OUT} 9900. Often, it is desirable to have a large beam width for BW_{OUT} 9900 of approximately 200 micrometers (200 um) in diameter or larger so as to reduce the optical intensity at the output mirror OM 2010. This would be the case if the IDG-OTFT laser is high in output power (e.g., in Watts to tens of Watts level). In that case, to couple into an output optical fiber OF 2070 with a fiber mode size diameter FMD 2075 that is smaller, like FMD 2075 of 8 microns or 20 microns, would require vertical emission from then output waveguide layer 1010, also to reduce the beam width BW_{OUT} 9900 (e.g., of 200 um) to fit the smaller fiber mode diameter FMD 2075 (of 8 um or 20 um). One way to achieve the mode size reduction is to use Fresnel lens structure FLS 9800 to focus the large vertical output beam to a smaller beam diameter to match the fiber mode size. Serving as an example for the purpose of illustration and not limitation, a Fresnel lens structure FLS 9800 can be made by deposition ˜2 microns thick nitrides (Si₃N₄ or AlN) on the grating surface with elliptical (or circular) grooves as shown in FIG. 15c. This would enable the large lateral width of the beam to be focused down to a smaller diameter when it reaches the fiber. The integrated Fresnel lens FLS 9800 can also be designed to compensate for the slight curvature in the surface-grating lines that is needed to match the converging curved wavefront.

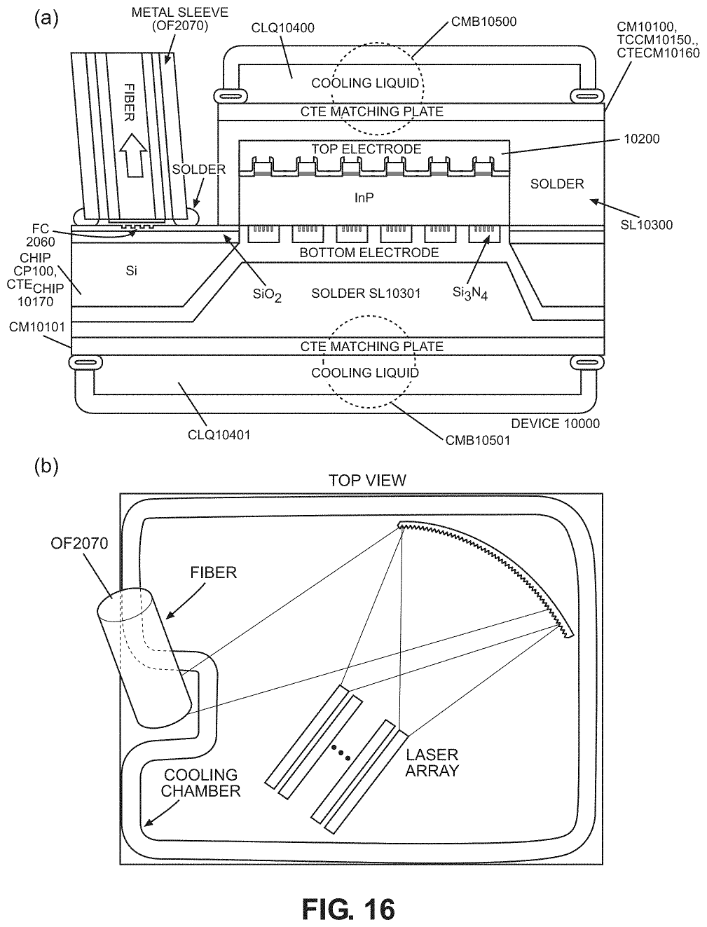

For the purpose of illustration and not limitation, FIG. 15d shows a cross section of the surface grating SG 9600 and the Fresnel lens FLS 9800 area showing the removal of the silicon substrate and metal coating 9500 that would help to reflect light back to the fiber. It also shows a tube 9700 holding the fiber that can be soldered down with solder 9750 in inert gas environment to provide a dust and moisture free hermetic sealing of the fiber coupling area 9770. The hermetic sealing would prevent the fiber end facet from power damage due to surface contamination over time. The cooling liquid 9780 below the coupling area would help to cool the area of the coupler FC 2060 (see also FIG. 16 later on chip cooling).

For the purpose of illustration and not limitation, if a wider bandwidth is needed, a vertical taper coupler can be fabricated. For example, a graded-refractive index micro lens with super-high numerical aperture, called super-GRIN lens that can be integrated on silicon chip to couple light from silicon waveguide to optical fiber. The super-GRIN lens or vertical taper-based fiber coupler would have wide spectral bandwidth of over 300 nm and can be used if optical spectral bandwidth wider than 60 nm is needed for future expansion.

For the purpose of illustration and not limitation, for the case of a super-GRIN lens or vertical taper on the edge of the chip, one can enlarge the vertical mode size to a 20-micron mode size by using the super-GRIN lens or the vertical taper, and also use an external lens to refocus the large beam width laterally. The use of such edge-emitting mode-transforming structures would be needed only when the spectral bandwidth is expanded to larger than 60 nm.

Cooling System Design

For the purpose of illustration and not limitation, in an exemplary embodiment, the chip is cooled by a cooling system and the cooling system Device 10000 is as shown in FIG. 16. The key element is a plate CM 10100 (shown in FIG. 16(a)) with high thermal conductivity given by TC_{CM} 10150 but with a coefficient of thermal expansion (CTE) CTE_{CM} 10160 close to matching the CTE CTE_{CHIP} 10170 of the chip CP100. This CP100 is the completely processed laser chip for laser IDG-OTFT, that started from the chip Device 1000 shown in FIG. 1. This is called a “CTE-matched heat-conduction plate” CM 10100. For the purpose of illustration and not limitation, in an exemplary embodiment, the chip is mainly made of silicon (CTE=2.6×10⁻⁶/K) with a thin layer of InP material bonded on top with CTE(InP)=4.6×10⁻⁶/K. The thermal conductivity and CTE of silicon are TC(Si)=149 W/m-K; n˜3.47; CTE(Si)=2.6×10⁻⁶/K) and that for InP are TC(InP)=68 W/m-K; n˜3.17; CTE(InP)=4.6×10⁻⁶/K). In this case, the CTE_{CHIP} 10170 is given by the CTE of silicon so that CTE_{CHIP}˜CTE(Si)=3×10⁻⁶/K as Silicon is thicker than the InP material bonded on the silicon SOI wafer.

For the purpose of illustration and not limitation, in an exemplary embodiment, the top of the chip is covered mainly by relatively thick metal 10200. As an example for illustration purpose, metal 10200 is mainly gold (˜10-100 microns thick with TC(gold)=314 W/m-K) and some nickel, for electrical contact and comprehensive heat spreading. The chip may also have layers of dielectric materials or polymer materials as part of the chip fabrication process. The dielectric material may include silicon nitride (Si₃N₄ or called SiN) or aluminum nitride (AlN) or silicon dioxide (SiO₂). The metal 10200 may also cover on top of these dielectric or polymer materials. Note that AlN is in general a good thermal conductor as solid and as deposited material (TC(solid-AlN) ˜285 W/m-K; CTE(AlN)=4.5×10⁻⁶/K; n˜2.1). AlN is also transparent at 1550 nm (it is a large bandgap UV material) and has been shown experimentally to be suitable for use in integrated optics at 1550 nm.

For the purpose of illustration and not limitation, in an exemplary embodiment, the top surface of the chip is mainly the N-doped InP layer that has the highest electrical resistance and hence is the main electrical heating source. This metalized P-side with metal layer 10200 on top can be soldered to the metalized “CTE-matching high-heat-conduction plate” CM 10100 with a solder layer SL 10300. The plate CM 10100 can also be metalized by depositing with nickel and gold to enable soldering. Serving as an example for illustration purpose, the soldering can be done by ultrasonic soldering equipment to remove any air void and the thickness of solder layer SL 10300 should in general be made very thin (only tens of microns) as solder has high CTE. As an example for illustration purpose, Gold-Tin solder can be used as the solder for solder layer SL 10300 as it has good heat conductance and also comparatively low CTE (CTE=16×10⁻⁶/K) comparing to that of Lead based solder (CTE=25-30×10⁻⁶/K). The solder layer SL 10300 should be thin comparing to the chip thickness of about 150 microns.

For the purpose of illustration and not limitation, in an exemplary embodiment, the main task of the CTE-matched high-heat-conduction plate CM 10100 is to transmit heat as much as possible to the cooling liquid CLQ 10400. The plate CM 10100 shall be thick enough to have the mechanical strength but otherwise as thin as possible to increase thermal conductance. For the purpose of illustration and not limitation, in an exemplary embodiment, a thickness of around 0.5-1 mm for CM 10100 can be used. A popular material choice for the CTE-matched plate CM 10100 is metal-diamond composite. For the purpose of illustration and not limitation, in an exemplary embodiment, the thermal conductivity of this CTE-matched thermal conducting plate CM 10100 is typically in the range of TC=500 W/m-K (achievable via a metal-diamond composite material), which is higher than that of metal. Diamond has very low CTE and metal has higher CTE than silicon. Such composite can be made CTE matched to that of silicon of CTE=2.6×10⁻⁶/K. The reason the CTE matching is important for this plate is because the temperature at the plate is expected to be high. At high enough cooling liquid flow rate, a heat removal rate of over 1-5 kW/cm² can be reached. For the purpose of illustration and not limitation, in an exemplary embodiment, this could have enough “cooling power per unit area” or “cooling power density” for the laser chip. For the purpose of illustration and not limitation, in an exemplary embodiment, the other side of the CTE plate CM 10100 would be a dimension-matching metal pieces that make a closed enclosure chamber CMB 10500 with the CTE-matching plate CM 10100 to allow cooling liquid CLQ 10400 to flow through. The cooling liquid CLQ 10400 side of the “CTE-matched high-heat-conduction plate” CM 10100 labelled as CLQS 10450 may be corrugated or made with cooling fins structure to increase the heat-transfer surface area so as to reduce the required cooling liquid flow rate. See also FIG. 15d on more detail illustration of the cooling of the fiber coupling area FC 2060.

For the purpose of illustration and not limitation, in another exemplary embodiment, the approach involves micro-channel liquid cooling. Microchannel cooling plate has many micro-size channels that are hundreds of microns in size to circulate the cooling liquid through. In the case with micro-channel cooling, the CTE matched high-heat-conduction plate CM 10100 is still used for the soldered contact to the chip but the liquid chamber CMB 10500 is replaced with liquid microchannels LMC 10700 (not shown in FIG. 16) Such micro-channel cooler is well known to those skilled in the art and can be very compact and efficient, requiring low cooling liquid flow rate (<0.51/min) and cooling liquid pressure (˜10 psi) to achieve a cooling rate of 1,000 W/cm². Such micro-channel cooler can be used for cooling high-power laser chip.

For the purpose of illustration and not limitation, assuming the cooling liquid is water, a cooling system that would provide a cooling rate of 1,000 W/cm², would require a water flow rate at 0.15-0.4 Gallon/min or 0.6-1.5 liter/min (assuming ˜25-10° C. water temperature increase). The heated water subsequently has to be cooled at ˜1,200 W assuming a laser power of 300 W and wall plug-efficiency of 25%. This water cooling can be achieved a commercial water-recirculating chiller. As an example, for the purpose of illustration, a small (air-cooled) water refrigerating chiller available with 1,200 W cooling capacity is about 12 lbs in weight, 6″×8″×11″ in size, and ˜720 W in wall-plug power (basically using 2 units of the chiller), each unit with up to 700 W cooling power, size 6″×8″×5.3″, 2 l/min water circulating rate, weighing 6 lbs, and ˜360 W in wall-plug power). Another possibility is a thermo-electric (TE) water chiller (air cooled) that would be 48 lbs in weight, 6″×8″×30″ in size, and 1200 W in wall-plug power (basically using 6 units of the TE based chiller, each unit with size 6″×8″×5″, weighing 8 lbs, and 200 W in wall-plug power).

For the purpose of illustration and not limitation, in an exemplary embodiment, if cooling to near ambient temperature is suitable, a forced air system with 1 kW cooling to cool the heated cooling liquid may be realizable with a very compact heat exchanger with 20 cm³ volume (˜4 cm×4 cm×4 cm). The power consumption for such blast-air cooling liquid cooling system is usually about 10% of the cooling power (i.e., ˜100 W for 1 kW cooling power). The laser chip would work at higher than room temperature but would become less effective when the laser power is high.

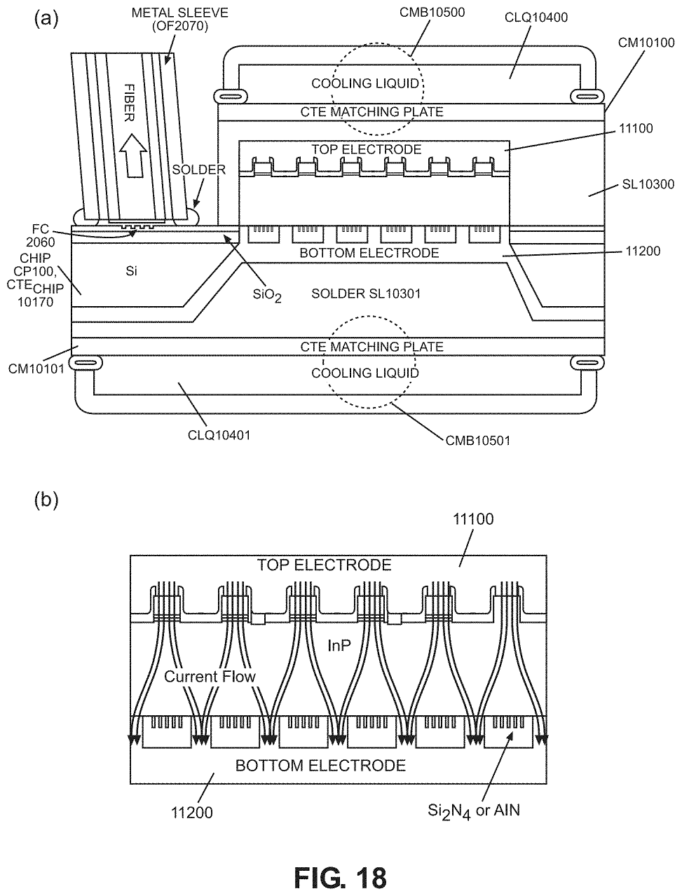

As an option, the bottom part of the chip CP 100 can also be bonded with the CTE matched plate CM 10101 (like CM 10100 at the top), the cooling chamber CMB 10501 (like CMB 10500 at the top), cooling liquid CLQ 10401 (like CLQ 10400 at the top), and solder SL10301 (like SL 10300 at the top). These are illustrated in FIG. 16(a) (and FIG. 18 too).

Electrical Contact

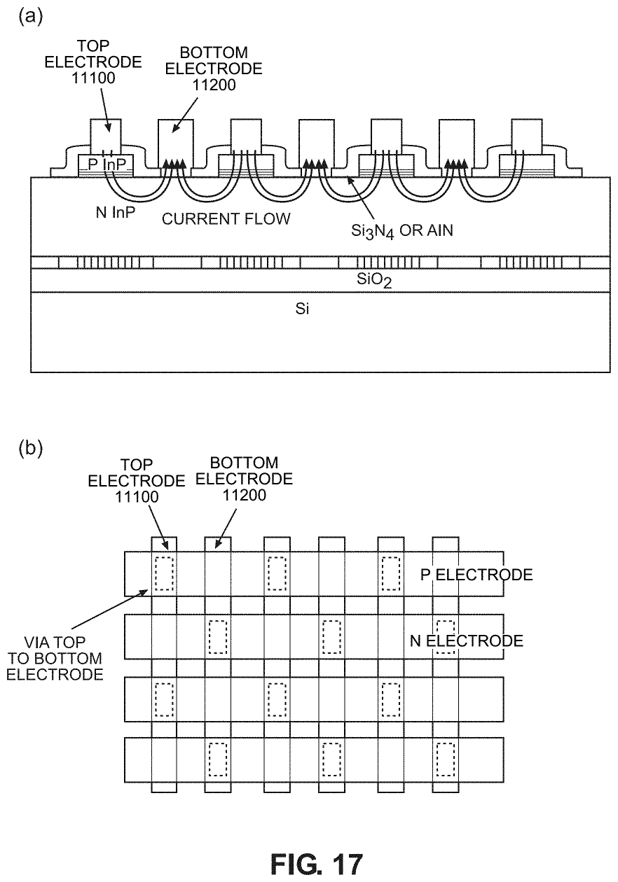

For the purpose of illustration and not limitation, in an exemplary embodiment, a schematic illustrating how the electrical contacts to the chip are made is shown in FIGS. 17-18. The top contact 11100 is directly deposited with the metal alloy for achieving good Ohmic contact (see FIG. 17(a) and FIG. 18(a)). As an example for the purpose of illustration and not limitation, the top contact is a P-contact made with a highly-doped P-doped InGaAs layer, and the bottom contact is a N-contact. The P-doped layer and P-Ohmic contact usually has the highest electrical bulk and surface contact resistances. Hence in that case, the P-contact at the top will generate the most heat energy that shall be removed as much as possible by the cooling structure mentioned earlier.

For the purpose of illustration and not limitation, in an exemplary embodiment, for the bottom contact 11200, there are two approaches to make the electrical contact to the bottom contact from an external electrical source.

The first approach is to open an access hole from the top to contact the bottom contact as shown by FIG. 17a. FIG. 17b shows the top view showing how the relatively narrow top and bottom electrodes along the waveguiding direction of the gain elements are connected in the perpendicular direction by a series of wide electrodes.

The second approach is to selectively etch away the bottom chip material layers. As an example for illustration and not limitation, one of the bottom layers at the active gain area is silicon. In that case, one can use KOH to etch away the silicon layer. Above the silicon layer is the 1-micron thick buried oxide (BOX) layer. This BOX layer can be selectively etched away as well using Hydrogen Fluoride (HF) solution. The BOX layer etching would then expose the top waveguiding silicon layer just below the optical gain material area. Serving as an example for illustration purpose, after the BOX layer etching, one can deposit the area with silicon nitride or aluminum nitride (from the exposed side) as a waveguiding cladding to protect the region just below the guided optical mode so as not to cause additional optical loss to the guided mode. The two wide regions next to the guided mode can be accessed for bottom metal contact 10200 to the highly N-doped InP bottom layer, as illustrated by FIG. 18. FIG. 18(b) shows more details for the chip part of FIG. 18(a).

Both methods are usable though the second method has the advantage of providing better heat dissipation from the bottom side, although it is estimated that less than 30% of the heat energy would travel by the bottom side simply because the top P-doped side has the main electrical heating and it is at least 4 times closer to the top metal than the bottom metal. Note that the contact metals would typically be electroplated to 10-50 microns thick to enable good heat spreading via the thick metal. This thick metal layer also serves to provide good electrical conduction to the top electrical contact.

### SUMMARY OF THE EXEMPLARY EMBODIMENTS

The present invention has overcome the aforementioned limitations of the prior arts on diffraction-gratings based semiconductor laser systems utilizing discrete optical components. It is an aim of the present invention to provide ultra-compact highly-integrated diffraction-grating based integrated semiconductor lasers with a thin-film-transfer structure, called IDG-OTFT Lasers, that are compact in size, light weight, mechanically rugged, low in manufacturing cost, high in electrical wall-plugged power efficiency, and in some cases high in optical power output, comparing to typical lasers based on discrete optical components.

In one embodiment of the present invention, a laser system is integrated on a single integrated chip via the use of an integrated curved diffraction grating combined with one or more integrated Bragg-grating reflectors, that enables a fully integrated diffraction-grating based laser that do not need the use of any optical lens.

In another embodiment of the present invention, one or more photonic devices are integrated on a substrate. The photonic devices comprise one or more optical gain material areas. One or more passive photonic components are fabricated on a passive waveguiding layer. The passive photonic components contain at least a curved optical grating and at least one wavelength-channel-combined-arm Bragg reflector. The method further transfers a thin layer of material capable of providing optical power amplification.

In another embodiment of the present invention, the wavelength-channel-combined-arm Bragg reflector is fabricated into a planar waveguiding layer.

In as yet another embodiment of the present invention, the wavelength-channel-combined-arm Bragg reflector is fabricated into a planar waveguiding layer with high-refractive index contrast, resulting in a broad optical bandwidth of reflection and transmission.

In as yet another embodiment of the present invention, the planar waveguiding layer is silicon.

In as yet another embodiment of the present invention, the number of reflecting teeth in the wavelength-channel-combined-arm Bragg reflector is adjusted to provide a highly reflecting beam-power reflector or a partially-transmitting beam-power reflector.

In as yet another embodiment of the present invention, the optical beam is confined in the direction perpendicular to the substrate surface via planar or channel waveguides, and a curved diffraction grating is fabricated into a planar waveguiding area with the surfaces of the grating teeth approximately perpendicular to the substrate plane.

In as yet another embodiment of the present invention, one side of the optical beam propagating path intersects with the wavelength-channel-combined-arm Bragg reflector, and another side of the optical beam propagating path intersects with the curved diffraction grating is positioned the mouth of a channel waveguide (called wavelength-channel-separated waveguide mouth).

In as yet another embodiment of the present invention, the optical power in a wavelength of light in the optical beam propagating toward the wavelength-channel-combined-arm Bragg-grating reflector is reflected back either fully or partially by the wavelength-channel-combined-arm Brag-grating reflector toward the curved diffraction grating and is further diffracted by the curved diffraction grating to enter the said wavelength-channel-separated waveguide mouth.

In as yet another embodiment of the present invention, there are two or more of the said waveguide mouths, with each mouth receiving a wavelength of the light beam reflecting back from the wavelength-channel-combined-arm Bragg reflector towards the grating.

In as yet another embodiment of the present invention, the beam entering the mouth of a channel waveguide is guided via a linear or a curvilinear path along a channel waveguide to an optical gain region.

In as yet another embodiment of the present invention, the optical gain region is composed of an active gain material layer forming a gain channel waveguide bonded on top of a passive transparent channel waveguide.

In as yet another embodiment of the present invention, the optical beam energy in the passive transparent channel waveguide is transferred from the passive channel waveguide to the gain material layer via laterally tapering structures on at least one of the passive channel waveguiding layer or the gain channel waveguide layer.

In as yet another embodiment of the present invention, the optical beam energy in the gain channel waveguide is transferred from the gain channel waveguide to the passive channel waveguide via laterally tapering structures on at least one of the passive channel waveguiding layer or the gain channel waveguide layer.

In as yet another embodiment of the present invention, the optical beam energy propagating through the gain region from the grating-facing waveguide mouth is entered into a passive channel waveguide. The beam in the passive channel waveguide is then reflected back either fully or partially via a Bragg-grating reflector.

In yet another embodiment of the present invention, the curved diffraction grating is designed such that the beam size in direction parallel to the plane of the substrate is larger at the wavelength-channel-combined-arm Bragg-grating reflector than at the wavelength-channel-separated waveguide mouth.

In yet another embodiment of the present invention, the curved grating is designed such that the beam size in direction parallel to the plane of the substrate (called the horizontal mode size) is small at the wavelength-channel-separated waveguide mouth, but is large at the wavelength-channel-combined-arm Bragg-grating reflector. There may be one or more than one waveguide mouths with each mouth receiving a wavelength channel. This enables the intensity at the wavelength-channel-combined-arm Bragg-grating reflector that would have higher optical power (by combining the many wavelength channels) to be made low or comparable to the intensity of the light beam at each of the wavelength-channel-separated waveguide mouth that would receive light energy in only one of the wavelength channels. The lowered intensity in the relatively higher-power beam at the wavelength-channel-combined-arm Bragg-grating reflector reduces the chance of optical damage at the wavelength-channel-combined-arm Bragg reflector region.

In as yet another embodiment of the present invention, the wavelength-channel-combined-arm Bragg-grating reflector is made of Bragg grating's teeth that are curved in shape (instead of linear in shape like a straight line), so as to achieve larger horizontal beam size and hence lower beam intensity at the wavelength-channel-combined-arm Bragg-grating reflector.

In as yet another embodiment of the present invention, the optical beam energy propagating towards the wavelength-channel-combined-arm Bragg-grating reflector is partially transmitted at the reflector to an optical-fiber coupler such as a surface-grating based optical fiber coupler, or a planar (horizontal) beam-transformer based optical fiber coupler.

In as yet another embodiment of the present invention, the spatial region that brings in the optical fiber to the optical-fiber coupler is hermetically sealed.

In as yet another embodiment of the present invention, the surface-grating based optical fiber coupler is composed of a surface grating that emits the beam in a direction approximately perpendicular to a substrate plane and a Fresnel lens structure that further reduces a beam diameter emitted to a smaller value.

In as yet another aspect of the present invention, each of the photonic devices is sandwiched from at least one of the top or the bottom via cooling fixtures that allow water cooling of the photonic device.

In the foregoing description, certain terms have been used for brevity, clearness, and understanding. No unnecessary limitations are to be inferred therefrom beyond the requirement of the prior art because such terms are used for descriptive purposes and are intended to be broadly construed. The different configurations, systems, and/or method steps described herein may be used alone or in combination with other configurations, systems and/or method steps. It is to be expected that various equivalents, alternatives and/or modifications are possible within the scope of the appended claims.

What is claimed is:

1. A method for integrating one or more photonic devices on a substrate, wherein the photonic devices comprise one or more optical gain material areas, the method comprising:
fabrication of one or more passive photonic components on a passive waveguiding layer,
wherein the passive photonic components contain at least a curved optical grating and at least a wavelength-channel-combined-arm Bragg reflector; and
transferring a thin layer of material capable of providing optical power amplification.

2. The method as claimed in claim 1, wherein the wavelength-channel-combined-arm Bragg reflector is fabricated into a planar waveguiding layer.

3. The method as claimed in claim 2, wherein the wavelength-channel-combined-arm Bragg reflector is fabricated into a planar waveguiding layer with high-refractive index contrast.

4. The method as claimed in claim 1, wherein the planar waveguiding layer is silicon.

5. The method as claimed in claim 1, wherein a number of reflecting teeth in the wavelength-channel-combined-arm Bragg reflector is adjusted to provide a highly reflecting beam-power reflector or a partially-transmitting beam-power reflector.

6. The method as claimed in claim 1, wherein the optical beam is confined in the direction perpendicular to the substrate surface via planar or channel waveguides, and a curved diffraction grating is fabricated into a planar waveguiding area with surfaces of grating teeth approximately perpendicular to the substrate plane.

7. The method as claimed in claim 6, wherein one side of the optical beam propagating path intersects with the wavelength-channel-combined-arm Bragg reflector, and another side of the optical beam propagating path intersects with the curved diffraction grating is positioned the mouth of a channel waveguide (called wavelength-channel-separated waveguide mouth).

8. The method as claimed in claim 7, wherein the optical power in a wavelength of light in the optical beam propagating toward the wavelength-channel-combined-arm Bragg-grating reflector is reflected back either fully or partially by the wavelength-channel-combined-arm Bragg-grating reflector toward the curved diffraction grating and is further diffracted by the curved diffraction grating to enter the wavelength-channel-separated waveguide mouth.

9. The method as claimed in claim 8, further comprising a plurality of waveguide mouths, with each waveguide mouth receiving a wavelength of the light beam reflecting back from the wavelength-channel-combined-arm Bragg reflector towards the grating.

10. The method as claimed in claim 9, wherein the light beam entering the mouth of a channel waveguide is guided via a linear or a curvilinear path along a channel waveguide to an optical gain region.

11. The method as claimed in claim 10, wherein the optical gain region is composed of an active gain material layer forming a gain channel waveguide bonded on top of a passive transparent channel waveguide.

12. The method as claimed in claim 11, wherein the optical beam energy in the passive transparent channel waveguide is transferred from the passive channel waveguide to the gain material layer via laterally tapering structures on at least one of the passive channel waveguiding layer or the gain channel waveguide layer.

13. The method as claimed in claim 12, wherein the optical beam energy in the gain channel waveguide is transferred from the gain channel waveguide to the passive channel waveguide via laterally tapering structures on at least one of the passive channel waveguiding layer or the gain channel waveguide layer.

14. The method as claimed in claim 10, wherein the optical beam energy propagating through the gain region from the grating-facing waveguide mouth is entered into a passive channel waveguide.

15. The method as claimed in claim 14, wherein the beam in the passive channel waveguide is reflected back either fully or partially via a Bragg-grating reflector.

16. The method as claimed in claim 6, wherein the curved diffraction grating is designed such that the beam size in direction parallel to the plane of the substrate is larger at the wavelength-channel-combined-arm Bragg-grating reflector than at the wavelength-channel-separated waveguide mouth.

17. The method as claimed in claim 7, wherein the wavelength-channel-combined-arm Bragg-grating reflector is made of Bragg-grating teeth that are curved in shape so as to achieve larger horizontal beam size and hence lower beam intensity at the wavelength-channel-combined-arm Bragg-grating reflector.

18. The method as claimed in claim 1, wherein a spatial region that brings an optical fiber to an optical-fiber coupler is hermetically sealed.

19. The method as claimed in claim 18, wherein the surface-grating based optical fiber coupler is composed of a surface grating that emits the beam in a direction approximately perpendicular to a substrate plane and a Fresnel lens structure that further reduces a beam diameter emitted to a smaller value.

20. The method as claimed in claim 1, wherein each of the photonic devices is sandwiched from at least one of the top or the bottom via cooling fixtures that allow water cooling of the photonic device.
